(19) United States
(12) Patent Application Publication
(10) Pub. No.: US 2023/0336154 A1
(43) Pub. Date: Oct. 19, 2023

(54) ELASTIC WAVE DEVICE AND COMMUNICATION DEVICE

(71) Applicant: KYOCERA Corporation, Kyoto-shi, Kyoto (JP)

(72) Inventor: Motoki ITO, Ikoma-shi (JP)

(73) Assignee: KYOCERA Corporation, Kyoto-shi, Kyoto (JP)

(21) Appl. No.: 18/010,681

(22) PCT Filed: Jun. 22, 2021
(86) PCT No.: PCT/JP2021/023593

§ 371 Date: Dec. 15, 2022

(30) Foreign Application Priority Data
Jun. 26, 2020 (JP) 2020-110211

(51) Int. Cl. H03H 9/17; H03H 9/13

(52) U.S. Cl. CPC H03H 9/171; H03H 9/132

(57) ABSTRACT

An acoustic wave device includes a composite substrate and an excitation electrode located on an upper surface of the composite substrate. The composite substrate includes a support substrate, a multilayer film, and a piezoelectric film overlapping the upper surface of the multilayer film. The multilayer film includes a plurality of acoustic films stacked on an upper surface of the support substrate. Adjacent ones of the acoustic films in a direction in which the acoustic films are stacked are made of different materials. The excitation electrode is located on an upper surface of the piezoelectric film. A side surface of the composite substrate includes a step portion. The step portion has a step-like shape with two or more steps ascending from the support substrate side to the piezoelectric film side in a direction from an outside to an inside with respect to the side surface.

### TECHNICAL FIELD

The present disclosure relates to an acoustic wave device that uses an acoustic wave and a communication device including the acoustic wave device.

### BACKGROUND OF INVENTION

Acoustic wave devices that use acoustic waves are known (e.g., Patent Literature 1 that will be mentioned below). An acoustic wave is, for example, a surface acoustic wave (SAW) or a bulk acoustic wave (BAW). An acoustic wave device includes, for example, a substrate at least the upper surface of which has piezoelectricity and an excitation electrode that applies a voltage to the upper surface of the substrate so as to excite an acoustic wave. Patent Literature 1 discloses an acoustic wave device including a reinforcement substrate, which serves as the above-mentioned substrate, an acoustic reflective layer located on the reinforcement substrate, and a piezoelectric layer located on the acoustic reflective layer. An excitation electrode is disposed on the piezoelectric layer. The acoustic reflective layer includes low impedance layers and high impedance layers alternately stacked on top of one another.

### CITATION LIST

### Patent Literature

Patent Literature 1: International Publication No. 2016/147688

### SUMMARY

In an aspect of the present disclosure, an acoustic wave device includes a composite substrate and an excitation electrode located on an upper surface of the composite substrate. The composite substrate includes a support substrate, a multilayer film, and a piezoelectric film. The multilayer film includes a plurality of acoustic films stacked on an upper surface of the support substrate. In the multilayer film, adjacent ones of the acoustic films in a direction in which the acoustic films are stacked are made of different materials. The piezoelectric film overlaps the upper surface of the multilayer film. The excitation electrode is located on an upper surface of the piezoelectric film. A side surface of the composite substrate includes a step portion. The step portion has a step-like shape with two or more steps ascending from the support substrate side to the piezoelectric film side in a direction from an outside to an inside with respect to the side surface.

In another aspect of the present disclosure, a communication device includes the above-described acoustic wave device, an antenna connected to the acoustic wave device, and an integrated circuit element connected to the acoustic wave device.

### BRIEF DESCRIPTION OF THE DRAWINGS

FIG. 1 is a plan view schematically illustrating a configuration of a principal portion of an acoustic wave device according to an embodiment.

FIG. 2 is a sectional view taken along line II-II of FIG. 1.

FIG. 3A is an enlarged view of a region Ma in FIG. 1.

FIG. 3B is an enlarged view of a region Mb in FIG. 2.

FIG. 4A is a sectional view illustrating a configuration of a step portion of a composite substrate according to a first variation.

FIG. 4B is a sectional view illustrating a configuration of a step portion of a composite substrate according to a second variation.

FIG. 5A is a plan view illustrating a configuration of a composite substrate according to a third variation.

FIG. 5B is a plan view illustrating a configuration of a composite substrate according to a fourth variation.

FIG. 6A is a plan view illustrating a configuration of a composite substrate according to a fifth variation.

FIG. 6B is a plan view illustrating a configuration of a composite substrate according to a sixth variation.

FIG. 7A is a graph illustrating characteristics relating to the impedance of a resonator according to an example.

FIG. 7B is a graph illustrating the resonant resistance of the resonator according to the example.

FIG. 8A is a graph illustrating a characteristic relating to the Bode-Q of the resonator according to the example.

FIG. 8B is a graph illustrating values of the Bode-Q of the resonator according to the example at a resonant frequency.

FIG. 9A is a graph illustrating the frequency of spurious generated in the resonator according to the example.

FIG. 9B is a graph illustrating the phase of the spurious generated in the resonator according to the example.

FIG. 10 is a circuit diagram schematically illustrating, as an example of how to use the acoustic wave device, a configuration of a branching filter.

FIG. 11 is a block diagram illustrating, as an example of how to use the acoustic wave device, a principal portion of a communication device.

### DESCRIPTION OF EMBODIMENTS

An embodiment of the present disclosure will be described below with reference to the drawings. Note that the drawings that will be referred to in the following description schematically illustrate objects, and the dimensional ratios and so forth of the objects illustrated in the drawings may sometimes be different from those of the actual objects. In addition, the dimensional ratios of the objects differ between the drawings.

Although an upward direction and a downward direction with respect to an acoustic wave device according to the present disclosure may be any directions, a rectangular coordinate system having an axis D1, an axis D2, and an axis D3 are illustrated in the drawings for the sake of convenience, and in the following description, terms such as “upper surface” and “lower surface” may sometimes be used while the positive D3-axis direction is defined as the upward direction. The phrase “when an object is viewed in plan view” or “when an object is viewed in perspective plan view” refers to the case where the object is viewed in the D3 direction unless otherwise stated. Note that the axis D1 is defined to be parallel to a direction in which an acoustic wave propagates along an upper surface of a piezoelectric film, which will be described later. The axis D2 is defined to be parallel to the upper surface of the piezoelectric film and perpendicular to the axis D1. The axis D3 is defined to be perpendicular to the upper surface of the piezoelectric film.

(Acoustic Wave Device)

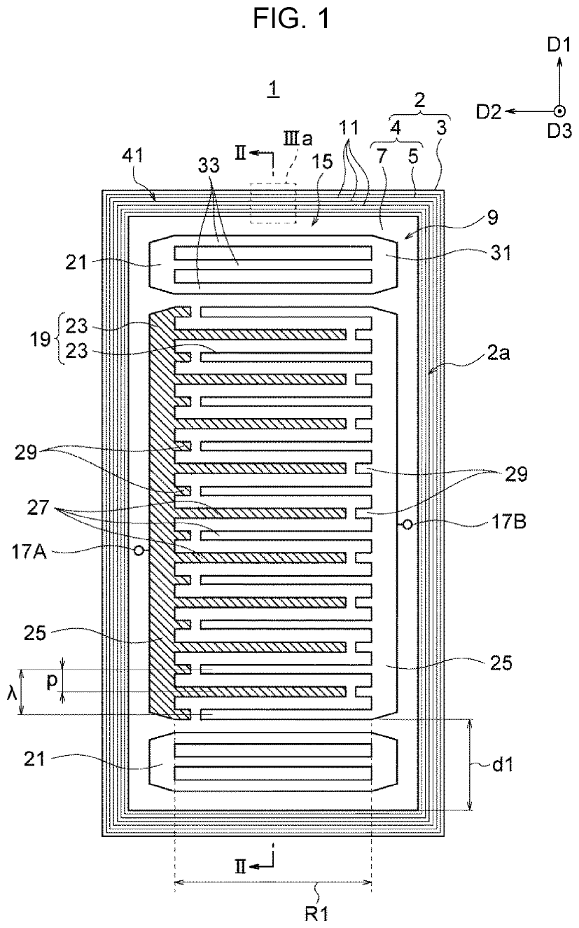

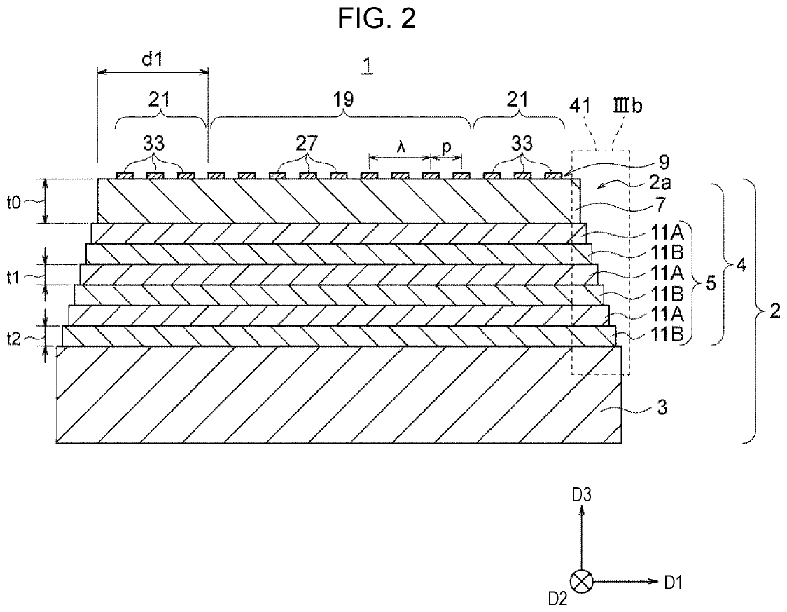

FIG. 1 is a plan view schematically illustrating the configuration of a principal portion of an acoustic wave device 1. FIG. 2 is a sectional view taken along line II-II of FIG. 1.

The acoustic wave device 1 includes, for example, a support substrate 3, a multilayer film 5 located on the support substrate 3, a piezoelectric film 7 located on the multilayer film 5, and a conductor layer 9 located on the piezoelectric film 7. The multilayer film 5 includes a plurality of acoustic films 11 (e.g., first films 11A and second films 11B), and the acoustic films 11 are stacked on top of one another. For example, the thickness of each layer (3, 5, 7, 9, and 11) is approximately uniform regardless of position in a planar direction (a direction parallel to a D1-D2 plane). Note that the combination of the multilayer film 5 and the piezoelectric film 7 may sometimes be referred to as a multilayer portion 4. The combination of the multilayer portion 4 and the support substrate 3 may sometimes be referred to as a composite substrate 2.

In the acoustic wave device 1, a voltage is applied to the piezoelectric film 7 by the conductor layer 9, so that an acoustic wave that propagates through the piezoelectric film 7 is excited. The acoustic wave device 1 forms, for example, a resonator and/or a filter that uses this acoustic wave. The multilayer film 5 contributes to confining the energy of the acoustic wave to the piezoelectric film 7 by, for example, reflecting the acoustic wave. The support substrate 3 contributes to, for example, reinforcing the strength of the multilayer film 5 and the strength of the piezoelectric film 7.

(Composite Substrate)

The material of the support substrate 3 is not particularly limited. For example, the material of the support substrate 3 is an insulating material. The insulating material is, for example, a resin or a ceramic. The insulating material may be a composite material obtained by impregnating a base material with a resin or may be a composite material obtained by mixing inorganic particles into a resin. The entire support substrate 3 may be made of a single material, or multiple layers made of different materials may be stacked on top of one another so as to form the support substrate 3. The thickness of the support substrate 3 may be suitably set and is, for example, larger than that of the piezoelectric film 7.

The support substrate 3 may be, for example, a member that does not directly affect the acoustic wave (from another standpoint, the electrical characteristics of the acoustic wave device 1) by ensuring a sufficient number of layers included in the multilayer film 5 and/or a sufficient thickness of the multilayer film 5. In this case, the degree of freedom regarding the material and the dimensions of the support substrate 3 is large. Note that the support substrate 3 may directly affect the acoustic wave.

The support substrate 3 may be made of a material having a thermal expansion coefficient lower than that of the piezoelectric film 7 or that of the multilayer portion 4 (the piezoelectric film 7 and the multilayer film 5). In this case, for example, the probability that the frequency characteristics of the acoustic wave device 1 will change due to temperature changes can be reduced. Examples of such a material include a semiconductor such as silicone, a single crystal such as sapphire, and a ceramic such as an aluminum oxide sintered compact.

As mentioned above, the multilayer film 5 includes the acoustic films 11 stacked on top of one another. Regarding the materials of the plurality of acoustic films 11, adjacent ones of the plurality of acoustic films 11 in a stacking direction in which the acoustic films 11 are stacked on top of one another (each two of the acoustic films 11 overlapping each other with no other acoustic film 11 interposed therebetween) are made of different materials (from another standpoint, have different acoustic impedances). Each two of the acoustic films 11 that are adjacent to each other have different acoustic impedances, so that, for example, the acoustic wave reflectivity at the interface between the two acoustic films 11 is relatively high. As a result, for example, leakage of the acoustic wave that propagates through the piezoelectric film 7 is reduced.

For the avoidance of doubt, acoustic impedance is theoretically a value that is obtained by the product of the density of a medium (the acoustic film 11) and the acoustic velocity of the medium. When there are two acoustic films from the standpoint of a manufacturing process, these acoustic films may be considered to be a single acoustic film 11 if they are adjacent to each other in the stacking direction and are made of the same material.

The number of types of materials of the acoustic films 11, the difference in acoustic impedance between the acoustic films 11 made of different materials, the inequality relationship between the acoustic impedance of each of the acoustic films 11 and the acoustic impedance of each of the other layers (the piezoelectric film 7 and the support substrate 3), and so forth may be suitably set. For example, two types of acoustic films 11 may be provided, or three or more types of acoustic films 11 may be provided. In addition, for example, some or all of the acoustic films 11 may have an acoustic impedance that is higher or lower than the acoustic impedance of the piezoelectric film 7 and/or the acoustic impedance of the support substrate 3.

In the present embodiment, the number of types of materials of the acoustic films 11 is two as an example. In other words, the multilayer film 5 includes the first films 11A and the second films 11B as the acoustic films 11, the first films 11A being made of a material different from the material of the second films 11B. The acoustic impedance of each of the first films 11A is different from that of each of the second films 11B, and the first films 11A and the second films 11B are adjacent to one another in the stacking direction. The specific material of the first films 11A and the specific material of the second films 11B may be suitably set such that the acoustic impedance of each of the first films 11A is different from that of each of the second films 11B.

For convenience of description, the acoustic impedance of each of the first films 11A is lower than the acoustic impedance of each of the second films 11B. Examples of the material of the first films 11A and the material of the second films 11B in this case are as follows. The material of the first films 11A may be, for example, silicon dioxide (SiO₂). The material of the second films 11B may be, for example, tantalum pentoxide (Ta₂O₅), hafnium oxide (HfO₂), zirconium dioxide (ZrO₂), titanium oxide (TiO₂), or magnesium oxide (MgO).

The number of films that are included in the multilayer film 5 and that are stacked on top of one another may be suitably set. In the case illustrated in FIG. 1 and FIG. 2, the first films 11A and the second films 11B are alternately stacked on top of one another, and the sum of the number of the stacked first films 11A and the number of the stacked second films 11B is three or more (more specifically, FIG. 2 illustrates six layers). Although the upper limit of the number of layers is not particularly limited, for example, the upper limit may be 12. That is to say, the number of layers may be, for example, 3 or more and 12 or less. However, unlike the case illustrated in FIG. 1 and FIG. 2, the multilayer film 5 may include a total of two layers, which are a single first film 11A and a single second film 11B.

The layer that is in contact with the piezoelectric film 7 may be one of the first films 11A or one of the second films 11B and is, for example, one of the first films 11A. Similarly, the layer that is in contact with the support substrate 3 may be one of the first films 11A or one of the second films 11B. Relating to the above, the sum of the number of the stacked first films 11A and the number of the stacked second films 11B in the multilayer film 5 may be an even number or an odd number.

The thickness of the multilayer film 5 may be suitably set. For example, the pitch of electrode fingers 27, which will be described later, is denoted by p. In this case, for example, a thickness t1 of each of the first films 11A may be set to 0.10 p or more or 0.14 p or more and may be set to 0.28 p or less or 0.26 p or less, and the above-mentioned lower limit and the above-mentioned upper limit may be suitably combined. For example, a thickness t2 of each of the second films 11B may be set to 0.08 p or more or 1.90 p or more and may be set to 2.00 p or less or 0.20 p or less, and the above-mentioned lower limit and the above-mentioned upper limit may be suitably combined as long as there is no inconsistency.

For example, the first films 11A and the second films 11B directly overlap one another (with no other layer interposed therebetween). However, an additional layer may be interposed between at least one of the first films 11A and the adjacent second film 11B so as to improve the degree of contact between them and/or to reduce diffusion. The thickness of the additional layer is set to be small to such an extent that its influence on characteristics is negligible. For example, the thickness of the additional layer is equal to or less than about 0.01λ (λ will be described later). In the description of the present disclosure, even in the case where such an additional layer is provided, the existence of the additional layer may sometimes be ignored. Similarly, even in the case where such an additional layer is provided between, for example, the piezoelectric film 7 and the multilayer film 5, the existence of the additional layer may sometimes be ignored.

The piezoelectric film 7 is made of, for example, a single crystal of lithium tantalate (LiTaO₃, hereinafter sometimes abbreviated to LT) or a single crystal of lithium niobate (LiNbO₃, hereinafter sometimes abbreviated to LN). The crystal systems of LT and LN are both a trigonal system with the piezoelectric point group 3m. The cut angle of the piezoelectric film 7 may be any one of various cut angles including commonly known cut angles. For example, the piezoelectric film 7 may be a rotated Y-cut X-propagation piezoelectric film. In other words, the acoustic wave propagation direction (the D1 direction) and the X axis may be substantially parallel to each other (the difference between them may be, for example, ±10°). In this case, the inclination angle of the Y axis with respect to the normal line (the D3 axis) of the piezoelectric film 7 may be suitably set.

Strictly speaking, the acoustic wave propagates in various directions. However, unless otherwise stated, the acoustic wave propagation direction mentioned in the present disclosure refers to a common propagation direction in an acoustic wave device. It can be said that the propagation direction is, for example, the direction in which the amount of energy to be transmitted of an acoustic wave that is intended to be used is the largest.

More specifically, in the case where the piezoelectric film 7 is made of LT, the piezoelectric film 7 may be represented by, for example, the Euler angles (φ, θ, ψ), that is, (0°±20°, −5° or greater and 65° or less, 0°±10°). From another standpoint, the piezoelectric film 7 is a rotated Y-cut X-propagation piezoelectric film, and the Y axis may be inclined at an angle of 85° or greater and 155° or less with respect to the normal line (the D3 axis) of the piezoelectric film 7. The piezoelectric film 7 that is represented by the Euler angles equivalent to the above may be used. Examples of the Euler angles equivalent to the above include (180°±20°, −65° or greater and 5° or less, 0°±10°) and that obtained by adding or subtracting 120° to or from φ.

In the case where the piezoelectric film 7 is made of LN, the piezoelectric film 7 may be represented by, for example, the Euler angles (φ, θ, ψ), that is, (0°, 0°±20°, X°), and “X°” is 0° or greater and 360° or less. In other words, “X°” can be any angle.

The thickness of the piezoelectric film 7 may be suitably set. For example, the pitch of electrode fingers 27, which will be described later, is denoted by p. In this case, for example, a thickness t0 of the piezoelectric film 7 may be set to 0.1 p or more or 0.2 p or more and may be set to 0.6 p or less or 0.5 p or less, and the above-mentioned lower limit and the above-mentioned upper limit may be suitably combined.

(Conductor Layer)

In the case illustrated in FIG. 1, the conductor layer 9 is formed so as to form a resonator 15. The resonator 15 is a so-called one-port acoustic wave resonator. The resonator 15 resonates once an electrical signal of a predetermined frequency has been input thereto from one of terminals 17A and 17B (FIG. 1), which are conceptually and schematically illustrated in FIG. 1, and can output the signal causing the resonance from the other of the terminals 17A and 17B. The terminals 17A and 17B are, for example, provided on the composite substrate 2. More specifically, the conductor layer 9 forms the terminals 17A and 17B on the piezoelectric film 7.

The resonator 15 includes, for example, an excitation electrode 19 and a pair of reflectors 21 located on opposite sides of the excitation electrode 19. Strictly speaking, the resonator 15 includes the piezoelectric film 7 and the multilayer film 5 relating to acoustic wave propagation. However, for convenience of description, the combination of the excitation electrode 19 and the pair of reflectors 21 may sometimes be referred to as the resonator 15.

The single resonator 15 (from another standpoint, the excitation electrode 19) may be provided on the single piezoelectric film 7, or a plurality of resonators 15 may be provided on the piezoelectric film 7 as will be described later. For ease of understanding of the drawings, FIG. 1 and FIG. 2 illustrate an aspect in which only one resonator 15 is provided. In general, a plurality of resonators 15 is provided on the single piezoelectric film 7. The following description may sometimes be based on an aspect in which the plurality of resonators 15 is provided unlike the case illustrated in the drawings.

The excitation electrode 19 is an IDT electrode and includes a pair of comb-shaped electrodes 23. Note that, in FIG. 1, one of the comb-shaped electrodes 23 is illustrated by hatching in order to improve the viewability. Each of the comb-shaped electrodes 23 includes, for example, a busbar 25, multiple electrode fingers 27 extending parallel to each other from the busbar 25, and dummy electrodes 29 projecting from the busbar 25 at positions between the multiple electrode fingers 27. The pair of comb-shaped electrodes 23 are arranged such that the plurality of electrode fingers 27 of one of the comb-shaped electrodes 23 interdigitate with the plurality of electrode fingers 27 of the other of the comb-shaped electrodes 23.

Each of the busbars 25 has, for example, an elongated shape having an approximately constant width and extending linearly in a direction approximately parallel to the acoustic wave propagation direction (the D1 direction). The pair of busbars 25 face each other in a direction (the D2 direction) that is perpendicular to the acoustic wave propagation direction. Note that the width of each of the busbars 25 is not necessarily constant, and the busbars 25 may be inclined with respect to the acoustic wave propagation direction.

Each of the electrode fingers 27 has, for example, an elongated shape having an approximately constant width and extending linearly in the direction (the D2 direction) that is perpendicular to the acoustic wave propagation direction. In each of the comb-shaped electrodes 23, the electrode fingers 27 are arranged in the acoustic wave propagation direction. The electrode fingers 27 of one of the comb-shaped electrodes 23 and the electrode fingers 27 of the other of the comb-shaped electrodes 23 are basically alternately arranged.

The pitch p of the electrode fingers 27 (e.g., the center-to-center distance between two of the electrode fingers 27 that are adjacent to each other) is basically constant in the excitation electrode 19. Note that the excitation electrode 19 may have a portion that is peculiar with respect to the pitch p. Examples of such a peculiar portion include a narrow-pitch portion in which the pitch p is narrower than the pitch p in a large portion (e.g., 80% or more) of the excitation electrode 19, a wide-pitch portion in which the pitch p is wider than the pitch p in a large portion of the excitation electrode 19, and a thinned-out portion in which a few of the electrode fingers 27 are substantially removed.

In the following description, the term “pitch p” refers to the pitch in a portion (most of the plurality of electrode fingers 27) excluding a peculiar portion, examples of which has been mentioned above, unless otherwise stated. In the case where the pitch of the electrode fingers 27 in the large portion excluding a peculiar portion also varies, the average value of the pitches of the electrode fingers 27 in the large portion may be used as the pitch p.

The number of the electrode fingers 27 may be suitably set in accordance with, for example, the electrical characteristics required for the resonator 15. Since FIG. 1 and FIG. 2 are schematic diagrams, the number of the electrode fingers 27 illustrated in FIG. 1 and FIG. 2 is smaller than the actual number. The actual number of the electrode fingers 27 arranged may be larger than that illustrated in FIG. 1 and larger than that illustrated in FIG. 2. The same applies to strip electrodes 33 of the reflectors 21, which will be described later.

For example, the lengths of the multiple electrode fingers 27 are the same as, and/or similar to, one another. Note that the excitation electrode 19 may be subjected to so-called apodization that causes the length (from another standpoint, the intersecting width) of the multiple electrode fingers 27 to vary in accordance with the position in the propagation direction. The lengths and the widths of the electrode fingers 27 may be suitably set in accordance with, for example, required electrical characteristics.

Each of the dummy electrodes 29 has, for example, a shape having an approximately constant width and projecting in a direction perpendicular to the acoustic wave propagation direction. The width of each of the dummy electrodes 29 is the same as, and/or similar to, that of each of the electrode fingers 27. The dummy electrodes 29 are arranged at a pitch the same as, and/or similar to, the pitch of the electrode fingers 27, and the ends of the dummy electrodes 29 of one of the comb-shaped electrodes 23 each face the end of one of the electrode fingers 27 of the other of the comb-shaped electrodes 23 with a gap formed therebetween. Note that the excitation electrode 19 does not need to include the dummy electrodes 29.

The pair of reflectors 21 are located on opposite sides of the plurality of excitation electrode 19 in the acoustic wave propagation direction. For example, the reflectors 21 may be in an electrically floating state, or a reference potential may be applied to the reflectors 21. The reflectors 21 are each formed in, for example, a grid-like pattern. In other words, each of the reflectors 21 includes a pair of busbars 31 facing each other and the plurality of strip electrodes 33 extending between the pair of busbars 31. In each of the reflectors 21, the pitch at which the strip electrodes 33 are arranged and the gap between one of the strip electrodes 33 and the adjacent electrode finger 27 are basically the same as, and/or similar to, the pitch of the electrode fingers 27.

The conductor layer 9 is made of, for example, a metal. The metal may be any suitable type of metal and is, for example, aluminum (Al) or an alloy containing Al as a main component (an Al alloy). The Al alloy is, for example, an aluminum-copper (Cu) alloy. Note that the conductor layer 9 may include a plurality of metallic layers. For example, a relatively thin layer that is made of titanium (Ti) may be provided between a layer made of Al or an Al alloy and the piezoelectric film 7 so as to improve the bonding strength between the layer made of Al or an Al alloy and the piezoelectric film 7. The thickness of the conductor layer 9 may be suitably set. For example, the thickness of the conductor layer 9 may be 0.04 p or more and 0.17 p or less.

Basically, the entire conductor layer 9 is made of the same material and has a constant thickness. For example, the excitation electrode 19, the reflectors 21, and a wiring line (with no reference sign) are made of the same material and have the same thickness. However, the conductor layer 9 may have a portion that is made of a different material and that has a different thickness. For example, the terminals 17A and 17B may each include a layer that is made of the same material as the excitation electrode 19, the reflectors 21, and the wiring line and that has the same thickness as the excitation electrode 19, the reflectors 21, and the wiring line and another layer that overlaps the layer and that is made of a different material.

Although not particularly illustrated, the upper surface of the piezoelectric film 7 may be covered with a protective film made of SiO₂, Si₃N₄, or the like from above the conductor layer 9. The protective film may be a multilayer body including multiple layers made of these materials. The protective film may simply suppress corrosion of the conductor layer 9 or may contribute to temperature compensation. In the case where, for example, the protective film is provided, an additional film that is made of an insulator or a metal may be provided on the upper surfaces or the lower surfaces of the excitation electrode 19 and the reflectors 21 in order to improve the reflection coefficient of an acoustic wave.

The configuration illustrated in FIG. 1 and FIG. 2 may be suitably packaged. For example, the packaging may be performed by mounting the configuration illustrated in FIG. 1 and FIG. 2 onto a substrate (not illustrated) such that the upper surface of the piezoelectric film 7 faces the substrate with a gap formed therebetween and sealing it with a mold resin from above, or the packaging may be wafer-level packaging in which a box-shaped cover is provided on the piezoelectric film 7.

Once a voltage has been applied to the pair of comb-shaped electrodes 23, the voltage is applied to the piezoelectric film 7 by the plurality of electrode fingers 27, and the piezoelectric film 7, which is a piezoelectric body, vibrates. As a result, an acoustic wave that propagates in the D1 direction is excited. The acoustic wave is reflected by the plurality of electrode fingers 27. Then, standing waves an approximately half-wavelength (λ/2) of which corresponds to the pitch p of the electrode fingers 27 occur. An electrical signal that is generated in the piezoelectric film 7 by the standing waves is taken out by the plurality of electrode fingers 27. Based on such a principle, the acoustic wave device 1 functions as a resonator having, as a resonant frequency, the frequency of the acoustic wave a half-wavelength of which is the pitch p. Note that the symbol “X” usually denotes wavelength. Although the wavelength of the actual acoustic wave may sometimes deviate from 2 p, when the symbol “X” is used in the following description, X indicates 2 p unless otherwise stated.

An acoustic wave of a suitable mode may be used. For example, in the configuration in which the piezoelectric film 7 is disposed on the multilayer film 5 as in the present embodiment, a slab-mode acoustic wave can be used. The propagation velocity (the acoustic velocity) of a slab-mode acoustic wave is greater than the propagation velocity of a general surface acoustic wave (SAW). For example, the propagation velocity of a slab-mode acoustic wave is 10000 m/s or greater, whereas the propagation velocity of a general SAW is 3000 m/s to 4000 m/s. Accordingly, by using a slab-mode acoustic wave, resonance and/or filtering in a relatively high frequency range may be easily achieved. For example, a resonant frequency of 5 GHz or higher can be obtained at the pitch p that is 1 μm or more.

(Step Portion of Composite Substrate)

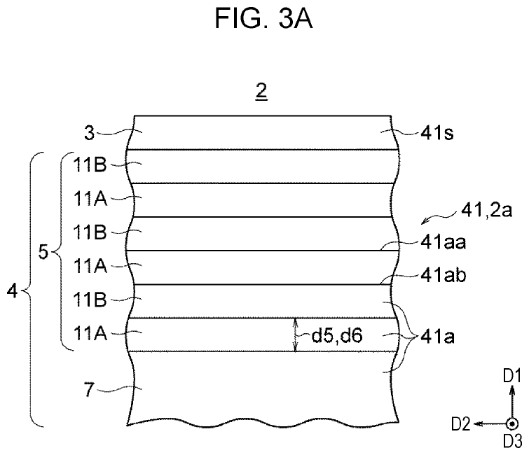

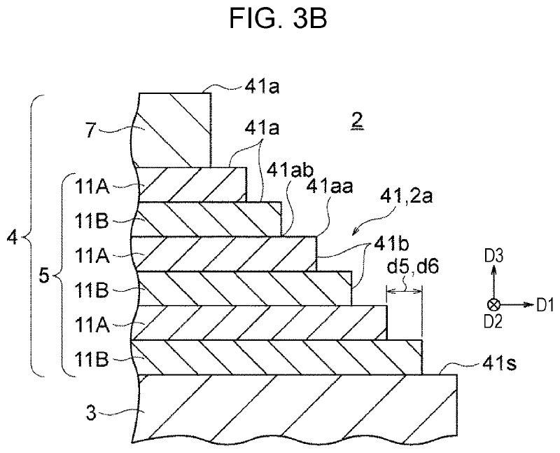

FIG. 3A is an enlarged view of a region Ma in FIG. 1. FIG. 3B is an enlarged view of a region Mb in FIG. 2.

As illustrated in FIG. 1, FIG. 2, FIG. 3A, and FIG. 3B, side surfaces 2a of the composite substrate 2 include a step portion 41 that has a step-like shape. Consequently, for example, an acoustic wave leaked from the resonator 15 to an area outside the resonator 15 is likely to be scattered when it reaches the side surfaces 2a of the composite substrate 2. As a result, spurious that is generated due to the acoustic wave reflected by the side surfaces 2a of the composite substrate 2 is reduced.

As illustrated in FIG. 1, the step portion 41 such as that mentioned above may be formed along the whole periphery of the composite substrate 2 when viewed in plan view, or unlike the case illustrated in FIG. 1, only a portion of the periphery of the composite substrate 2 may include the step portion 41. An example of the latter case can be an aspect in which the step portion 41 is formed only at two of the four sides of the composite substrate 2, which has a substantially rectangular shape when viewed in plan view, the two sides facing each other, in such a manner as to extend across the entire length or part of the length of the two sides. These two sides are, for example, two sides that are perpendicular to the acoustic wave propagation direction (the D1 direction). The two sides may be two sides that extend in the acoustic wave propagation direction.

Note that, for example, the case where a step-like shape is formed across the four side surfaces 2a of the composite substrate 2 as illustrated in FIG. 1 may be perceived as an aspect in which a single step portion 41 is formed so as to extend along the whole periphery of the composite substrate 2 or as an aspect in which a total of four step portions 41 are formed such that each of the side surfaces 2a includes one of the four step portions 41. Similarly, the case where a step-like shape is distributed in the circumferential direction of the composite substrate 2 when viewed in plan view may be perceived as an aspect in which a single step portion 41 is formed or as an aspect in which multiple step portions 41 are formed. For convenience of description, however, all the aspects in the description of the embodiment are basically described based on the premise that the single step portion 41 is provided.

The positional relationship between the excitation electrode 19 and the step portion 41 may be suitably set. For example, when viewed in plan view, assume that an imaginary region R1 (FIG. 1) is formed by extending the arrangement region of the plurality of electrode fingers 27 along the acoustic wave propagation direction to an area outside the composite substrate 2. In this case, the step portion 41 may or may not include a portion that is located in the imaginary region R1. Note that, the aspect in which the step portion 41 is formed along the whole periphery of the composite substrate 2 as in the case illustrated in FIG. 1 is an example of an aspect in which the step portion 41 includes a portion that is located in the imaginary region R1.

More specifically, two imaginary regions R1 can be assumed to be formed in two directions that are the positive D1 direction and the negative D1 direction with respect to the single excitation electrode 19. In the case where a plurality of excitation electrodes 19 is provided, the number of the imaginary regions R1 can be assumed to be twice the number of the excitation electrodes 19 (note that the imaginary regions R1 may sometimes overlap each other). The step portion 41 may be partially located in any of two or more imaginary regions R1. For example, the step portion 41 may be partially located only in some of multiple imaginary regions R1 or may be partially located in all the imaginary regions R1. In addition, for example, the step portion 41 may be partially located in at least one of the multiple imaginary regions R1, the at least one imaginary region R1 being formed on one side of one of the excitation electrodes 19 that is closest to at least one of the side surfaces 2a of the composite substrate 2 in the D1 direction, the one side being closer to the at least one of the side surfaces 2a than the other sides of the one excitation electrode 19.

For example, only a portion of the step portion 41 may be located in a specific imaginary region R1 or in all the imaginary regions R1 (i.e., the step portion 41 may include a portion that is not located in a specific imaginary region R1 or a portion that is not located in any of the imaginary regions R1), or the step portion 41 may be composed of a portion that is located in a specific imaginary region R1 or in all the imaginary regions R1. The step portion 41 may be located in specific one or more imaginary regions R1 or all the imaginary regions R1 in such a manner as to extend across the full width (the length in the D2 direction in FIG. 1) of each imaginary region R1, extend along a large portion of the width (e.g., 80% or more of the width of each imaginary region R1) (the case illustrated in FIG. 1), or extend along a portion of the width of each imaginary region R1.

The shape and the dimensions of the step portion 41 may be approximately constant regardless of position in the circumferential direction of the composite substrate 2 when viewed in plan view, or the shape and the dimensions of the step portion 41 may vary in accordance with the position in the circumferential direction. For example, the shape and the dimensions of a portion of the step portion 41 that is located at at least one of the side surfaces 2a extending along the D1 direction may be different from the shape and the dimensions of a portion of the step portion 41 that is located at at least one of the side surfaces 2a extending along the D2 direction.

However, an aspect in which the shape and the dimensions of the step portion 41 are approximately constant regardless of position in the circumferential direction of the composite substrate 2 when viewed in plan view will be mainly described below as an example. Thus, the following description of the shape and the dimensions of the step portion 41 may be applied to an arbitrary position (e.g., any one of the four side surfaces 2a) in the circumferential direction of the composite substrate 2 unless otherwise stated and as long as they do not conflict with each other.

More specifically, as illustrated in FIG. 1, FIG. 2, FIG. 3A, and FIG. 3B, the step portion 41 has a step-like shape ascending from the support substrate 3 to the piezoelectric film 7 in a direction from the outside to the inside with respect to the side surfaces 2a of the composite substrate 2 (the negative D1 direction in the area illustrated in FIG. 3A and FIG. 3B). In other words, surfaces that correspond to the surfaces of the actual steps that are to be stepped on (hereinafter referred to as a “treads 41a”) are oriented in the positive D3 direction (the direction in which the upper surface of the piezoelectric film 7 is oriented), and the proximity of the treads 41a to the positive D3 side increases with increasing proximity of the treads 41a to the inner side of the composite substrate 2 when viewed in plan view.

Portions of the upper surfaces of the films (11 and/or 7) included in the multilayer portion 4, the portions being exposed upward, form the treads 41a. More specifically, in the case illustrated in FIG. 3A and FIG. 3B, each of the acoustic films 11 includes a portion that is located further outside the side surfaces 2a of the composite substrate 2 than the piezoelectric film 7 or the other acoustic films 11 overlapping the upper surface of the acoustic film 11 (in the area illustrated in FIG. 3A and FIG. 3B, the portion is located in the positive D1 direction from the piezoelectric film 7 or the other acoustic films 11). As a result, the upper surface of this portion forms one of the treads 41a. Since the piezoelectric film 7 is the uppermost layer of the multilayer portion 4, the upper surface of the piezoelectric film 7 is not covered with the other films (the acoustic films 11) of the multilayer portion 4. The outer edge of the piezoelectric film 7 is located further inside the side surfaces 2a of the composite substrate 2 than the outer edge of the upper surface of the multilayer film 5 (in the area illustrated in FIG. 3A and FIG. 3B, the outer edge of the piezoelectric film 7 is located in the negative D1 direction from the outer edge of the upper surface of the multilayer film 5). As a result, the upper surface of the piezoelectric film 7 forms one of the treads 41a.

Note that the phrase “be exposed upward” relates to the relative positions of the support substrate 3, the plurality of acoustic films 11, and the piezoelectric film 7. For example, as mentioned above, the upper surface of the piezoelectric film 7 may be covered with the protective layer from above the conductor layer 9, and also in this case, the upper surface of the piezoelectric film 7 may sometimes be described as being exposed upward in such a manner as to form one of the treads 41a. For example, as mentioned above, a relatively thin layer may be interposed between the acoustic films 11, and even in the case where this thin layer covers the upper surface of one of the acoustic films 11, the upper surface of this acoustic film 11 may sometimes be described as being exposed upward in such a manner as to form one of the treads 41a. For example, an insulator (considered as a member different from the composite substrate 2 in this case) may be provided on the support substrate 3 so as to cause the step portion 41 to be buried by surrounding the multilayer portion 4, and also in such a case, the upper surfaces of the acoustic films 11 may sometimes be described as being exposed upward in such a manner as to form the respective treads 41a. In either case, the side surfaces of the piezoelectric film 7 and the side surfaces of the acoustic films 11 are located at positions that are displaced from one another, so that an acoustic wave scattering effect can be obtained.

Among the upper surface of the support substrate 3, the upper surfaces of the acoustic films 11, and the upper surface of the piezoelectric film 7, the upper surface that is exposed at the lowermost position (the upper surface of the support substrate 3 in the case illustrated in FIG. 3B) is a surface that functions as a reference for steps (hereinafter referred to as a “reference surface 41s”). In other words, the reference surface 41s is not included in the treads 41a. The number of steps refers to the number of steps from the reference surface.

For example, in the case illustrated in FIG. 3B, a step-like shape having a total of seven steps including the six layers, which are the acoustic films 11, and the single layer, which is the piezoelectric film 7, is formed. In other words, in the case illustrated in FIG. 3B, the step portion 41 is formed in a step-like shape with two or more steps. From another standpoint, in the case illustrated in FIG. 3B, one of the films (7 or 11) of the multilayer portion 4 forms one of the steps. The upper surfaces of the six layers, which are the acoustic films 11, and the upper surface of the single layer, which is the piezoelectric film 7, form the seven treads 41a in total. The upper surface of the piezoelectric film 7 forms the uppermost tread 41a.

The treads 41a and the reference surface 41s each have, for example, a planar shape extending in the D1 direction. Note that the treads 41a and the reference surface 41s may be inclined with respect to the D1 direction. For example, a direction in which a large portion of the upper surface of the piezoelectric film 7 (or either at least one of the acoustic films 11 or the support substrate 3) or the region of the upper surface in which the excitation electrode 19 is disposed extends is parallel to the D1 direction. In this case, each of the treads 41a may be inclined with respect to the D1 direction such that one end of the tread 41a that faces an area outside the side surfaces 2a of the composite substrate 2 (the positive D1 side in the area illustrated in FIG. 3A and FIG. 3B) is positioned closer to the positive D3 side or the negative D3 side than the other end of the tread 41a. Irregularities may be formed on the treads 41a and the reference surface 41s.

The side surfaces of the films (7 and 11) of the multilayer portion 4 form wall surfaces 41b that vertically extend from the treads 41a. Each of the wall surfaces 41b may have a suitable shape. For example, each of the wall surfaces 41b may have a planar shape (as illustrated in FIG. 3B) or does not necessarily have a planar shape. In the latter case, for example, when viewed in cross section as illustrated in FIG. 3B, each of the wall surfaces 41b may have a curved shape or a shape having a corner, or the overall shape thereof may be a concave shape, a convex shape, a protruding shape, or a recessed shape. Alternatively, the shape of each of the wall surfaces 41b may have irregularities.

In the case illustrated in FIG. 3B, the wall surfaces 41b each have a planar shape extending in the D3 direction. In other words, the upper edge and the lower edge of each of the wall surfaces 41b are located at the same position in a direction parallel to the D1-D2 plane. Note that the upper edge and the lower edge of each of the wall surfaces 41b may be located at different positions in the direction parallel to the D1-D2 plane. For example, the upper edge may be located further toward inside of the side surfaces 2a of the composite substrate 2 (the negative D1 side in FIG. 3B) than the lower edge or may be located further toward outside of the side surfaces 2a of the composite substrate 2 (the positive D1 side in FIG. 3B) than the lower edge. In other words, each of the wall surfaces 41b (which is not limited to having a planar shape) may be inclined upward with respect to the D3 direction or may be inclined downward with respect to the D3 direction when seen as a whole.

In the following description, an aspect in which the wall surfaces 41b extend in the D3 direction will be mainly described as an example. Accordingly, the following description of the shape of an outer edge 41aa (or an inner edge 41ab) of each of the treads 41a when viewed in plan view can be considered as the description of the shape of each of the wall surfaces 41b when viewed in plan view. Thus, here, the description of the shape of each of the wall surfaces 41b when viewed in plan view will be omitted. Note that the following description of the shape of the outer edge 41aa (or the inner edge 41ab) when viewed in plan view may be applied to the shape (e.g., a schematic shape) of each of the wall surfaces 41b when viewed in plan view in an aspect in which the wall surfaces 41b do not extend in the D3 direction.

An edge of each of the treads 41a on a step descending side will be referred to as the outer edge 41aa. Another edge of each of the treads 41a on a step ascending side will be referred to as the inner edge 41ab. However, regarding the tread 41a formed of the upper surface of the piezoelectric film 7, the inner edge 41ab is not defined. Note that, in the case illustrated in FIG. 3B, as mentioned above, the wall surfaces 41b vertically extending from the treads 41a are perpendicular to the treads 41a. Consequently, in the plan view illustrated in FIG. 3A, the inner edge 41ab of one of the treads 41a and the outer edge 41aa of another one of the treads 41a that is one step above the tread 41a overlap each other.

Each of the outer edges 41aa is formed of the outer edge of the upper surface of one of the films (7 or 11), the film including the corresponding tread 41a having the outer edge 41aa. Each of the inner edges 41ab is formed of the outer edge of the lower surface of a film overlapping one of the films (7 or 11) that includes the tread 41a having the inner edge 41ab. The shapes of the outer edges 41aa and the shapes of the inner edges 41ab may be suitably set. In the case illustrated in FIG. 3A, the outer edges 41aa and the inner edges 41ab each have a linear shape. In the case illustrated in FIG. 3A, in the side surfaces 2a of the composite substrate 2 that extend in the D2 direction, the outer edges 41aa and the inner edges 41ab extend in the D2 direction. In the side surfaces 2a of the composite substrate 2 that extend in the D1 direction, the outer edges 41aa and the inner edges 41ab extend in the D1 direction. In the case illustrated in FIG. 3A, the outer edges 41aa and the inner edges 41ab are parallel to one another. Other shapes of the outer and inner edges 41aa and 41ab will be described later with reference to the drawings relating to variations.

The length of each of the treads 41a from the inner edge 41ab to the outer edge 41aa (the depth of each tread 41a) will be referred to as a length d5. In a portion of the step portion 41 that is located in the imaginary regions R1, the length of each of the treads 41a in the acoustic wave propagation direction (D1) will be referred to as a length d6. The length d6 is a type of the length d5. In the following description, the reference sign “d5” of the length d5 will be basically used, the description of the length d5 may be considered as the description of the length d6 as long as there is no inconsistency.

In the case illustrated in FIG. 3B, the length d5 is constant regardless of position in the circumferential direction of the composite substrate 2. The treads 41a have the same length d5. The length d5 of one of the treads 41a may be smaller than, equal to, or larger than the height of the step including the tread 41a (in the D3 direction) or may be smaller than, equal to, or larger than the pitch p. As will be described later, the length d5 may sometimes vary depending on the position in the circumferential direction of the composite substrate 2 and/or depending on the treads 41a. Regarding the step portion, in at least a portion of the treads 41a and/or at least a portion of one of the treads 41a, the length d5 may be set to 0.2 p or more, 0.5 p or more, or 1 p or more.

(Design with Consideration of Effect of Step Portion)

The step portion 41 is provided in the manner described above, so that an acoustic wave leaked from the resonator 15 is likely to be scattered at the side surfaces 2a of the composite substrate 2, and accordingly, spurious that is generated in the resonator 15 is reduced. As a result, for example, a size reduction effect may be obtained by reducing a portion that contributes to the reduction in spurious.

For example, the number of the strip electrodes 33 of each of the reflectors 21 may be reduced to be smaller than that in the related art. For example, in general, the number of the strip electrodes 33 included in one of the reflectors 21 is 20 or more or 30 or more. (The same may apply to the technology according to the present disclosure.) In the case where the step portion 41 is provided, the number of the strip electrodes 33 included in one of the reflectors 21 may be 10 or less or 5 or less. Note that the lower limit of the number of the strip electrodes 33 included in one of the reflectors 21 may be, for example, 2, 3, or 4.

For example, the distance (the shortest distance) between the excitation electrode 19 and the outer edge of the piezoelectric film 7 in the D1 direction (the acoustic wave propagation direction) is denoted by d1 (FIG. 1 and FIG. 2). In this case, the distance d1 may be shorter than that in the related art. For example, the distance d1 may be 10 p (5λ) or less and/or 10 μm or less. Note that the center-to-center distance between one of the electrode fingers 27 of the excitation electrode 19 that is closest to one of the reflectors 21 and one of the strip electrodes 33 of the reflector 21 that is farthest from the excitation electrode 19 is approximately a length obtained by multiplying the pitch p by the number of the strip electrodes 33 of the reflector 21. Thus, when the distance d1 is set to 10 p, the distance d1 substantially corresponds to a region in which the ten strip electrodes 33 are arranged.

(Variations of Step Portion)

Variations of the step portion will be described below. In the following description, only differences from the embodiment (or the variation described earlier. The same applies hereinafter in this paragraph.) will be basically described. Matters not specifically mentioned may be the same as, and/or similar to, those in the embodiment or may be inferred from the embodiment. In the description of a configuration that corresponds to or that is the same as, and/or similar to, the configuration of the embodiment, the reference signs used in the description of the configuration of the embodiment may sometimes be used even if there are differences between these configurations.

(First Variation)

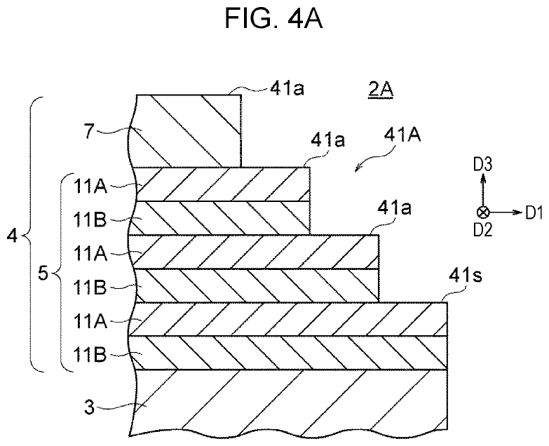

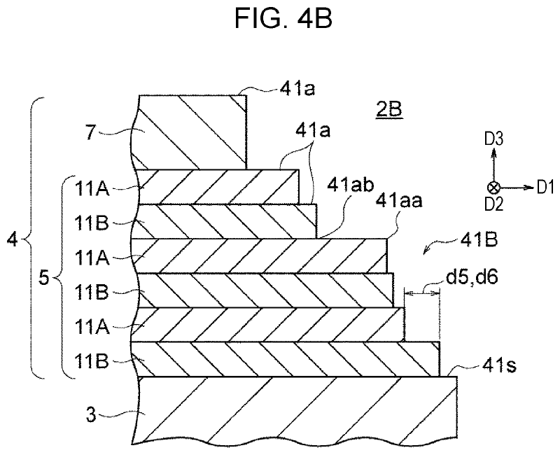

FIG. 4A is a sectional view illustrating a configuration of a step portion 41A of a composite substrate 2A according to the first variation and corresponds to FIG. 3B.

As illustrated in FIG. 4A, at least one step of the step portion 41A may include two or more films (7 and/or 11) of the multilayer portion 4. In the case illustrated in FIG. 4A, the steps including the treads 41a formed of the upper surfaces of the acoustic films 11 includes two acoustic films 11. Alternatively, although not particularly illustrated, the piezoelectric film 7 and at least one of the acoustic films 11 underlying the piezoelectric film 7 may form a single step, or three or more of the films may form a single step. The steps may include the same number of layers or may include different numbers of layers.

When the gap (see the length d5) between the side surfaces of two films (7 and/or 11) that are adjacent to each other in the stacking direction is relatively small, these two films may be considered to form a single step together. Although the gap in this case varies depending on the dimensions of the composite substrate 2 and the like, the gap is, for example, smaller than 0.1 p or smaller than 0.01 p.

The upper surface of the support substrate 3 may be covered with at least one of the acoustic films 11. In other words, one of the upper surfaces of the acoustic films 11 that are exposed upward, the one upper surface being located at the lowest position (the upper surface of the acoustic film 11 which is the second layer from the bottom in the case illustrated in FIG. 4A) may form the reference surface 41s of the step portion 41A. Note that, in the case illustrated in FIG. 4A, the number of steps from the reference surface 41s is three.

From another standpoint, the step portion 41A does not necessarily extend over the entire side surfaces of the composite substrate 2A from the upper surface of the support substrate 3 to the upper surface of the piezoelectric film 7 and may be located at only a portion of the side surfaces of the composite substrate 2A. In this case, the portion may be a portion on the piezoelectric-film-7 side or a portion on the support-substrate-3 side or may be a portion between the piezoelectric film 7 and the support substrate 3.

For example, in the case illustrated in FIG. 4A, the step portion 41A includes the upper surface of the piezoelectric film 7 as the uppermost tread 41a, and thus, it can be said that the step portion 41A is located at a portion on the piezoelectric-film-7 side. Unlike the case illustrated in FIG. 4A, for example, the piezoelectric film 7 may project further toward outside the side surfaces of the composite substrate 2A than the acoustic films 11 underlying the piezoelectric film 7. In this case, it cannot be said that the piezoelectric film 7 forms part of a step portion that has a shape ascending from the support substrate 3 to the piezoelectric film 7 in a direction from the outside to the inside with respect to the side surfaces of the composite substrate 2A. In the manner described above, a step portion may be formed at a portion between the piezoelectric film 7 and the support substrate 3 or at a portion on the support-substrate-3 side.

Note that the configuration in which at least one step includes two or more films and the configuration in which a step portion is formed only in a portion of a region extending from the upper surface of the support substrate 3 to the upper surface of the piezoelectric film 7 are not necessarily coupled to each other and may be applied separately to the step portion.

For example, in FIG. 4A, the support substrate 3 may project further toward outside the side surfaces of the composite substrate 2A than one of the acoustic films 11 that is the lowermost layer, so that a step portion in which at least one step includes two or more films may be formed over the entire region extending from the upper surface of the support substrate 3 to the upper surface of the piezoelectric film 7. Alternatively, for example, in FIG. 3B, the support substrate 3 or the acoustic film 11 that is close to the support substrate 3 may not project further toward outside the side surfaces of the composite substrate 2 than the film overlapping the upper surface of the support substrate 3 or the upper surface of the acoustic films 11, so that a step portion in which each step includes a single film may be formed only at a portion on the piezoelectric-film-7 side.

Although not particularly illustrated, the side surfaces of all the acoustic films 11 may be flush with one another while the upper surface of the support substrate 3 serves as the reference surface 41s such that the upper surface of the uppermost acoustic film 11 forms the tread 41a of the first step and that the upper surface of the piezoelectric film 7 forms the tread 41a of the second step, so that a step portion that includes the two steps may be formed. In other words, the first step may include all the acoustic films 11. Note that, when comparing to such a configuration, it can be said that the step portion 41 illustrated in FIG. 3B or the step portion 41A illustrated in FIG. 4A includes the treads 41a formed of the upper surfaces of the acoustic films 11 located below the uppermost acoustic film 11.

(Second Variation)

FIG. 4B is a sectional view illustrating a configuration of a step portion 41B of a composite substrate 2B according to the second variation and corresponds to FIG. 3B.

As illustrated in FIG. 4B, the lengths d5, which are the depths of the treads 41a, may be different from one another among the treads 41a (and the reference surface 41s). In the case illustrated in FIG. 4B, as in the embodiment, the step portion 41B is formed over the entire region extending from the upper surface of the support substrate 3 to the upper surface of the piezoelectric film 7, and each step includes only one of the films (7 or 11). However, the aspect in which the lengths d5 are different from one another may be applied to the aspect in which at least one step includes two films (FIG. 3A) or may be applied to the aspect in which the step portion is located only at a portion of the region extending from the upper surface of the support substrate 3 to the upper surface of the piezoelectric film 7.

The lengths d5 of all the treads 41a may be different from one another, or only some of the treads 41a may have the lengths d5 different from the length d5 of the other treads 41a. Among the plurality of treads 41a, two treads 41a having different lengths d5 may be two treads 41a that are adjacent to each other (with no other tread 41a interposed therebetween) in the D3 direction or may be two treads 41a that are not adjacent to each other. The tread 41a having a relatively long or short length d5 may be positioned on the piezoelectric-film-7 side, the support-substrate-3 side, or a center side between the piezoelectric film 7 and the support substrate 3 in the D3 direction. Alternatively, the tread 41a may be disposed such that these tendencies do not occur.

The differences between the lengths d5 may be suitably set. For example, when comparing the lengths d5 of any two treads 41a or when comparing the longest length d5 and the shortest length d5 among the lengths d5 of the treads 41a, the difference between them may be shorter than, equal to, or longer than one-half of the shortest length d5. In addition, the difference between them may be 0.1 p or more, 0.2 p or more, or 0.5 p or more.

(Third Variation)

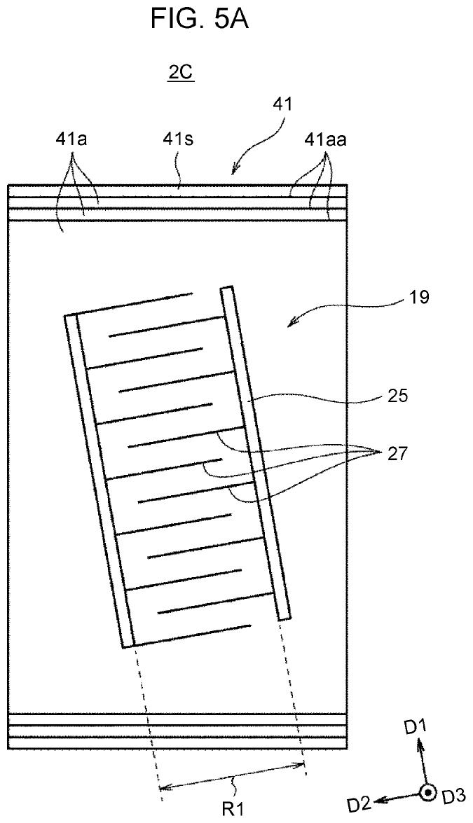

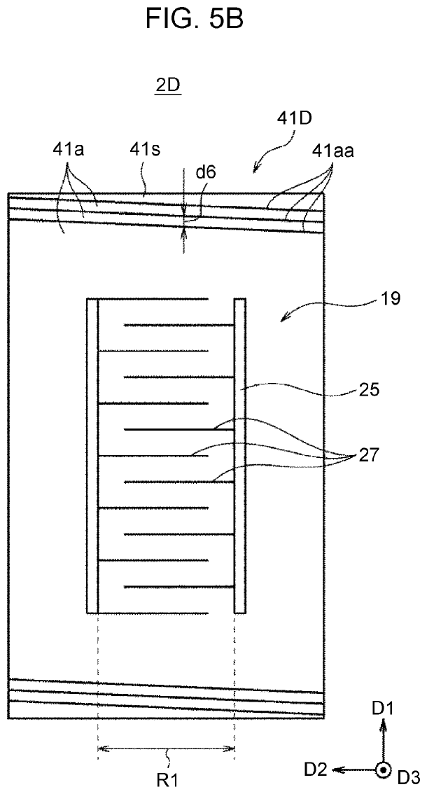

FIG. 5A is a plan view illustrating a configuration of a composite substrate 2C according to the third variation. In FIG. 5A, the reflectors 21 are not illustrated for convenience of description. FIG. 5A illustrates the excitation electrode 19 more schematically than FIG. 1. Although the number of steps included in the step portion 41 may be any number, the number of steps illustrated in FIG. 5A is smaller than the number of steps illustrated in FIG. 1 for convenience of description.

As illustrated in FIG. 5A, the side surfaces of the composite substrate 2C may be inclined with respect to the D1 direction (the acoustic wave propagation direction) and the D2 direction (the direction perpendicular to the acoustic wave propagation direction). Although not particularly illustrated, the composite substrate 2C may have a shape (e.g., a parallelogram shape) that is not a rectangular shape, and some of the four sides of the composite substrate 2C may extend in the D1 direction or the D2 direction.

From another standpoint, the outer edges 41aa of a portion of the step portion 41, the portion being located one side in the acoustic wave propagation direction (the D1 direction) with respect to the excitation electrode 19, (e.g., a portion of the step portion 41 that is located in the imaginary region R1) may be inclined with respect to the direction (the D2 direction) that is perpendicular to the propagation direction. The inclination angle may be any angle. For example, the inclination angle may be 1 degree or greater, 5 degrees or greater, 10 degrees or greater, or 30 degrees or greater. Although FIG. 5A illustrates the step portion 41 of the embodiment as an example, the aspect in which the outer edges 41aa are inclined with respect to the acoustic wave propagation direction may be applied to the step portions (e.g., 41A and 41B) according to the variations.

Note that, as mentioned in the description of the embodiment, the step portion 41 may be formed along the whole periphery of the composite substrate 2C when viewed in plan view, or only a portion of the periphery of the composite substrate 2C may include the step portion 41. FIG. 5A illustrates an aspect in which only the two sides of the composite substrate 2C that face each other in a direction approximately parallel to the D1 direction include the step portion 41.

(Fourth Variation)

FIG. 5B is a plan view illustrating a configuration of a composite substrate 2D according to the fourth variation and is a diagram the same as, and/or similar to, FIG. 5A.

In the fourth variation, like the third variation, the outer edges 41aa of a portion of the step portion 41, the portion being located one side in the acoustic wave propagation direction (the D1 direction) with respect to the excitation electrode 19, (e.g., a portion of the step portion 41 that is located in the imaginary region R1) are inclined with respect to the direction (the D2 direction) that is perpendicular to the propagation direction. The inclination angle and so forth are the same as, and/or similar to, those in the third variation. Note that, in the fourth embodiment, each of the four side surfaces of the support substrate 3 extends in the D1 direction or the D2 direction.

From another standpoint, when viewed in plan view, a step portion 41D includes a portion that is located in the imaginary region R1 and in which the outer edges 41aa are inclined with respect to a portion of the side surfaces of the composite substrate 2D, the portion being located in the imaginary region R1. From another standpoint, the length of the reference surface 41s in the D1 direction varies depending on the position in the D2 direction.

In the case illustrated in FIG. 5B, all the outer edges 41aa are inclined with respect to the side surfaces of the composite substrate 2D (or with respect to the D2 direction), and the outer edges 41aa are parallel to one another. However, unlike the case illustrated in FIG. 5B, only some of the outer edges 41aa may be inclined with respect to the side surfaces of the composite substrate 2D. In other words, the outer edges 41aa may be inclined with respect to one another. From another standpoint, the length d6 of each of the treads 41a in the D1 direction may vary depending on the position in the D2 direction.

FIG. 5B illustrates an aspect in which each of the outer edges 41aa is inclined with respect to the side surfaces of the support substrate 3 and/or the other outer edges 41aa has been applied to the embodiment. However, the inclination of the outer edges 41aa may be applied to the variations. For example, it is obvious that the inclination of the outer edges 41aa may be applied to the first and second variations. In addition, for example, the inclination of the outer edges 41aa may be applied to the third variation, and a portion of the side surfaces of the support substrate 3 that is located in the imaginary region R1, a portion of the outer edge 41aa that is located in the imaginary region R1, and the D1 direction may be inclined with respect to one another.

(Fifth Variation)

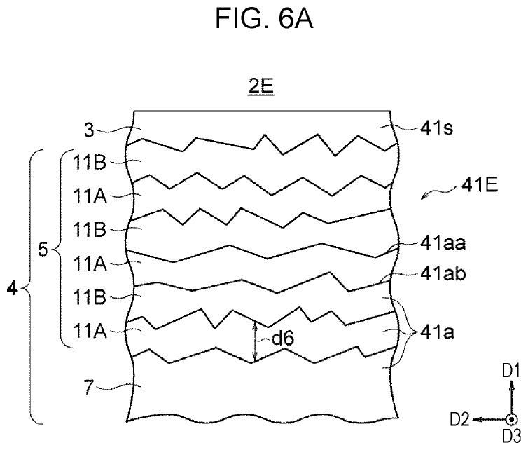

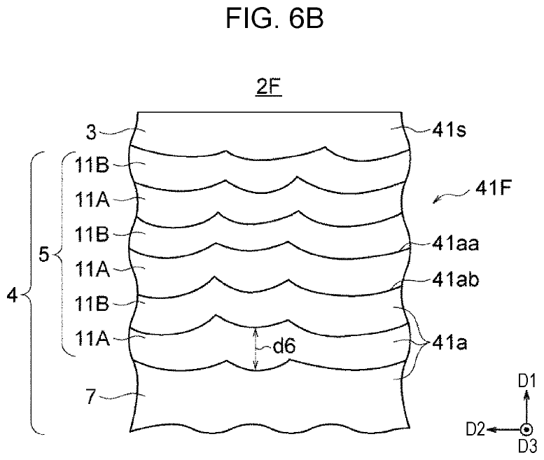

FIG. 6A is a plan view illustrating a configuration of a step portion 41E of a composite substrate 2E according to the fifth variation and corresponds to FIG. 3A.

As illustrated in FIG. 6A, the outer edges 41aa (or the inner edges 41ab) of the treads 41a do not necessarily have a linear shape when viewed in plan view. In the case illustrated in FIG. 6A, each of the outer edges 41aa extends while being repeatedly bent to opposite sides (extends in a serpentine manner). In other words, each of the outer edges 41aa has the shape of a wave. As in the third and fourth variations (FIG. 5A and FIG. 5B), when viewed in plan view, it can be said that the outer edges 41aa each having the shape of a wave includes a portion that is inclined with respect to the D1 direction and/or the side surfaces of the support substrate 3 in the imaginary region R1 (FIG. 1).

The specific shape of the wave may be suitably set. For example, the wave may be a sine wave, a triangular wave, a rectangular wave, a sawtooth wave, or a wave that is obtained by altering these waves. The shape of the wave may contain a straight line (a line segment) and/or a curved line. The shape a half-wavelength of the wave may be symmetric with respect to a line passing through the maximum value or the minimum value like a sine wave or may be asymmetric with respect to the line passing through the maximum value or the minimum value like a sawtooth wave. The shape of the wave for a plurality of wavelengths may be regular, or regularity may not be found. In other words, the values of appropriate parameters such as amplitude and/or period may or may not be constant.

The relationship among the plurality of outer edges 41aa may also be suitably set. For example, the shapes (the shapes of the waves) of some (two or more) of the outer edges 41aa or all the outer edges 41aa may be the same as each other or different from each other. In other words, some of the outer edges 41aa or all the outer edges 41aa may have the same or different of appropriate parameters such as amplitude and/or period. In the case where the wave periods of some of the outer edges 41aa or all the outer edges 41aa are the same as, and/or similar to, one another, the phases (positions in the D2 direction in the area illustrated in FIG. 6A) may match one another or may be different from one another. The distance between the outer edges 41aa may or may not be constant regardless of position in a direction along the outer edges 41aa.

From another standpoint, the length d5 (FIG. 3A), which is the depth of each of the treads 41a, may vary depending on the position in the direction along the outer edge 41aa. Note that, in the aspect in which the outer edges 41aa and the inner edges 41ab are not parallel to one another as in the present variation, the length d5 of each of the treads 41a may be defined by the length of the tread 41a in a predetermined direction (e.g., a direction approximately perpendicular to the outer edge 41aa) or may be defined by the shortest distance from each point on the outer edge 41aa to the inner edge 41ab.

In the imaginary region R1 (FIG. 1), the length d6 of each of the treads 41a in the acoustic wave propagation direction may be defined as mentioned above. The case illustrated in FIG. 6A is an example of an aspect in which the length d6 varies depending on the position in the direction (the D2 direction) perpendicular to the acoustic wave propagation direction. The variation range of the length d6 in this case may be suitably set. For example, in one of the treads 41a, the difference between the longest length d6 and the shortest length d6 in one imaginary region R1 may be one-tenth or more, one-fifth or more, or one-half or more of the longest length d6. Note that the upper limit of the difference is the difference when the shortest length d6 is zero and is equal to the longest length d6. For example, in one of the treads 41a, the difference between the longest length d6 and the shortest length d6 in one imaginary region R1 may be 0.1 p or more, 0.5 p or more, or 1 p or more.

In the case illustrated in FIG. 6A, when viewed in plan view, the outer edge of the upper surface (the reference surface 41s) of the support substrate 3 has a linear shape. In other words, the waviness of this outer edge (e.g., the magnitude thereof may be evaluated by the arithmetic mean roughness) is smaller than the waviness of each of the outer edges 41aa of the treads 41a. From another standpoint, the surface roughness of each of the side surfaces of the support substrate 3 is smaller than the surface roughness of the side surfaces of the films (7 and/or 11) of the multilayer portion 4. For example, in one imaginary region R1, the arithmetic mean roughness of the outer edge of the upper surface of the support substrate 3 or each of the side surfaces of the support substrate may be 0.5 p or less or 0.1 p or less. (Note that the arithmetic mean roughness is smaller than that of each of the outer edges 41aa or that of each of the side surfaces of the films of the multilayer portion 4).

However, unlike the case illustrated in FIG. 6A, the magnitude of the waviness of the outer edge of the upper surface of the support substrate 3 may be equal to or greater than the magnitude of the waviness of the outer edge 41aa of at least one of the treads 41a. In such a case, whether the outer edge 41aa includes a portion that is inclined with respect to the outer edge of the upper surface of the support substrate 3 or with respect to at least one of the side surfaces of the support substrate 3 may be determined by, for example, the inclination of the outer edge 41aa with respect to an imaginary straight line or an imaginary plane that is set to such that the arithmetic mean roughness of the outer edge of the upper surface of the support substrate 3 or the arithmetic mean roughness of each of the side surfaces of the support substrate 3 is minimized in the entire side surfaces or one imaginary region R1.

The configuration according to the fifth variation (e.g., the configuration in which each of the outer edges 41aa does not have a linear shape) may be applied not only to the embodiment but also to the other variations. For example, it is obvious that the configuration according to the fifth variation is applicable to the first variation (FIG. 4A) and the third variation (FIG. 5A). In addition, for example, the description of the configuration according to the second variation (FIG. 4B) in which the treads 41a have different lengths d5 (d6) may be suitably applied to an arbitrary portion of the outer edges 41aa (a single point on the outer edges 41aa may be focused) in the fifth variation. When assuming a virtual outer edge 41aa that is set such that the arithmetic mean roughness of at least one of the outer edges 41aa in the fifth variation is minimized within a predetermined length range (e.g., the width of the imaginary region R1), the description of the second variation and/or the fourth variation (FIG. 5B) may be applied to the virtual outer edge 41aa.

(Sixth Variation)

FIG. 6B is a plan view illustrating a configuration of a step portion 41F of a composite substrate 2F according to the sixth variation and corresponds to FIG. 3A.

In the sixth variation, like the fifth variation, the outer edges 41aa of the treads 41a each have the shape of a wave. As mentioned in the description of the fifth variation, the specific shape of the wave may be any one of various shapes, and in the sixth variation, the shape of the wave contains a curved line as an example.

More specifically, in the case illustrated in FIG. 6B, each of the outer edges 41aa contains a curved line that is concave toward the step descending side (the positive D1 side in the area illustrated in FIG. 6B). In one of the outer edges 41aa, a plurality of contiguous concave curves forms a wavy shape in which the connection points between the concave curves are each a maximal value. The curvature of each curve may be suitably set. In the case illustrated in FIG. 6B, the wavy shapes of the outer edges 41aa are the same as, and/or similar to, one another, and their phases are close to one another. Accordingly, variations in the length d6, which is the depth of each of the treads 41a, with respect to direction along the outer edges 41aa (the D2 direction in the area illustrated in FIG. 6B) are relatively small. Obviously, the variations in the length d6 may be large unlike the case illustrated in FIG. 6B.

(Method of Manufacturing Acoustic Wave Device)

A method of manufacturing the acoustic wave device 1 except for a step of forming the step portion 41 may be generally the same as a commonly known method or may use a commonly known method. The step portion 41 can be manufactured by various methods.

For example, the plurality of films (11 and 7) included in the multilayer portion 4 may be sequentially formed and patterned starting from the lowermost film. In this case, the step portion 41 may be formed by arranging the outer edges of the films that are defined by a mask such that the outer edge of each of the films is located further inward than the outer edge of the other film underlying the film. The outer edges 41aa of the step portion 41 can have any shape depending on the pattern of the mask defining the outer edges of the films.

For example, the acoustic wave device 1 may be manufactured by dividing a wafer including a plurality of acoustic wave devices 1 (by separating the wafer into the individual acoustic wave devices 1). The wafer may be cut by using a dicing blade into the individual acoustic wave devices 1. In this case, cutting is performed from above the acoustic wave devices 1 while appropriately setting the pressure that is applied by the blade to the wafer, so that portions (edges) of the upper layers that are near the blade are more likely to become cracked than portions of the lower layers. By utilizing this phenomenon, the step portion 41 may be formed such that the outer edge of each of the layers is located further inward than the outer edge of the other layer underlying the layer. Each of the outer edges 41aa of the step portion 41 in this case is likely to have, for example, a wavy shape as in the fifth and sixth variations (FIG. 6A and FIG. 6B).

Instead of dividing the wafer by using a blade, the wafer may be divided by using a laser. In this case, by appropriately setting the intensity of a laser beam, a waste margin of the wafer is removed such that the outer edge of each of the layers is located further inward than the outer edge of the other layer underlying the layer. Such a method may be used to obtain the step portion 41.

As described above, in the present embodiment and its variations, the acoustic wave device 1 includes the composite substrate 2 (and 2A to 2F) (hereinafter, only reference signs according to the embodiment may sometimes be mentioned as representatives) and the excitation electrode 19 located on the upper surface of the composite substrate 2. The composite substrate 2 includes the support substrate 3, the multilayer film 5, and the piezoelectric film 7. The multilayer film 5 includes the plurality of acoustic films 11, which is stacked on the upper surface of the support substrate 3, and each two of the acoustic films 11 that are adjacent to each other in the stacking direction are made of different materials. The piezoelectric film 7 overlaps the upper surface of the multilayer film 5. The excitation electrode 19 is located on the upper surface of the piezoelectric film 7. The side surfaces 2a of the composite substrate 2 include the step portion 41 having a step-like shape with two or more steps ascending from the support substrate 3 to the piezoelectric film 7 in the direction from the outside to the inside with respect to the side surfaces 2a.

Thus, for example, an undesirable acoustic wave is scattered at the side surfaces 2a of the composite substrate 2 as mentioned above, and spurious that is generated due to the undesirable acoustic wave reflected by the side surfaces 2a can be reduced. Since the step portion 41 has a step-like shape with two or more steps ascending from the support substrate 3 to the piezoelectric film 7 in the direction from the outside to the inside with respect to the side surfaces 2a, when seen as a whole, the step portion 41 has an inclined surface that is inclined outward in the direction from the piezoelectric film 7 toward the support substrate 3. Consequently, an acoustic wave that reaches the step portion 41 is likely to be reflected to the side (the negative D3 side) opposite to the piezoelectric-film-7 side. As a result, spurious that is generated due to an undesirable acoustic wave can be more easily reduced compared with the aspect in which irregularities are simply formed on the side surfaces 2a.

The step portion 41 may include the treads 41a formed of the upper surfaces of the acoustic films 11 located below the acoustic film 11 that is the uppermost layer in the multilayer film 5. In other words, the side surfaces of the multilayer film 5 may include at least one of the treads 41a included in the step portion 41.

In this case, for example, in the side surfaces of the multilayer film 5, an effect the same as, and/or similar to, the effect mentioned above is obtained. In other words, an undesirable acoustic wave is scattered and reflected downward. Therefore, the probability that an undesirable acoustic wave leaked from the piezoelectric film 7 to the multilayer film 5 will return to the piezoelectric film 7 may be easily reduced.

The step portion 41 may include the upper surface of the piezoelectric film 7 as the tread 41a of the uppermost step. At least two steps including the uppermost step may each include one or two films selected from the group consisting of the plurality of acoustic films 11 and the piezoelectric film 7.

In this case, it can be said that, in the step portion 41, an upper portion of the multilayer portion 4 (the multilayer film 5 and the piezoelectric film 7) serves as a single step having a relatively small height (the length in the D3 direction, which is a so-called riser). On the other hand, the energy of the leaked acoustic wave is large at the upper portion of the multilayer portion 4. Thus, for example, the above effects of scattering an undesired acoustic wave and reflecting the undesired acoustic wave downward are improved.

The step portion 41 may extend from the upper surface of the support substrate 3 to the upper surface of the piezoelectric film 7. Each step may include one or two films selected from the group consisting of the plurality of acoustic films 11 and the piezoelectric film 7.

In this case, it can be said that the step portion 41 includes a portion that serves as a single step having a relatively small height over the entire the side surfaces of the multilayer portion 4. Therefore, for example, an effect of scattering an undesirable acoustic wave is improved.

At least two continuous steps of the step portion 41 may each include only one film selected from the group consisting of the plurality of acoustic films 11 and the piezoelectric film 7 (see the variations excluding the second variation (FIG. 4A)).

In this case, for example, the height of each step of the step portion 41 is small, and thus, the effect of scattering an undesirable acoustic wave is improved.

The excitation electrode 19 may include the plurality of electrode fingers 27 arranged in the acoustic wave propagation direction (the D1 direction) when the piezoelectric film 7 is viewed in plan view. The step portion 41 may be located in the imaginary region R1, which is formed by extending the arrangement region of the plurality of electrode fingers 27 along the D1 direction to an area outside of the composite substrate 2, when the piezoelectric film 7 is viewed in plan view.

In this case, for example, the step portion 41 is located in a direction in which an acoustic wave is most likely to leak. As a result, the effects of scattering and reflecting an undesired acoustic wave are improved.

In at least one step of the step portion 41, when the piezoelectric film 7 is viewed in plan view, the descending-side edge (the outer edge 41aa) of the tread 41a may include a portion that is inclined with respect to the direction (the D2 direction) perpendicular to acoustic wave propagation direction and that is located in the imaginary region R1 (FIG. 5A to FIG. 6B).

In this case, for example, when viewed in plan view, an acoustic wave that has leaked from the excitation electrode 19 in the D1 direction and reached the step portion 41 is likely to be reflected in a direction that is inclined with respect to the D1 direction. As a result, the probability that the reflected acoustic wave will return to the excitation electrode 19 and cause spurious is reduced.

In at least one step of the step portion 41, when the piezoelectric film 7 is viewed in plan view, the descending-side edge (the outer edge 41aa) of the tread 41a may include a portion that extends while being repeatedly bent to opposite sides (i.e., a portion having a wavy shape) and that is located in the imaginary region R1 (FIG. 6A and FIG. 6B).

In this case, for example, an acoustic wave is scattered not only by the step portion 41 when viewed in cross section but also by the wavy shapes of the outer edges 41aa (from another standpoint, the wall surfaces 41b) when viewed in plan view. As a result, an effect of reducing spurious that is generated due to an acoustic wave reflected at the side surfaces 2a of the composite substrate 2 is improved.

At least one step of the step portion 41 includes the tread 41a formed of the upper surface of one of the plurality of acoustic films 11, and when the piezoelectric film 7 is viewed in plan view, the at least one step of the step portion 41 may include a portion that is located in the imaginary region R1 and in which the length d6 of the tread 41a in a direction parallel to the acoustic wave propagation direction (the D1 direction) varies depending on the position in the direction (the D2 direction) perpendicular to the D1 direction (FIG. 6A and FIG. 6B).

In this case, for example, the manner in which an acoustic wave that is reflected at the outer edge 41aa of the tread 41a (from another standpoint, the wall surface 41b of the layer whose upper surface serves as the tread 41a) and an acoustic wave that is reflected at the inner edge 41ab of the tread 41a (from another standpoint, the wall surface 41b of the layer overlapping the upper surface including the tread 41a) are superimposed varies depending on the position in the D2 direction. As a result, for example, the energy of the reflected acoustic waves may be easily dispersed. Accordingly, spurious is reduced.

At least two steps of the step portion 41 may include a tread formed of the upper surface of one of the plurality of acoustic films 11. The treads of these two steps may have different lengths d6 in the acoustic wave propagation direction (the D1 direction) in the imaginary region R1 (FIG. 4B, FIG. 6A, and FIG. 6B).

In this case, for example, the manner in which an acoustic wave that is reflected at the outer edges 41aa of the treads 41a and an acoustic wave that is reflected at the inner edges 41ab of the treads 41a are superimposed varies between the steps of the step portion 41. As a result, for example, the energy of the reflected acoustic waves may be easily dispersed. Accordingly, spurious is reduced.

In at least one step of the step portion 41, when the piezoelectric film 7 is viewed in plan view, the descending-side edge (the outer edge 41aa) of the tread 41a may include a portion that is located in the imaginary region R1 and that is inclined with respect to a portion of the side surfaces of the support substrate 3, the portion of the side surfaces being located in the imaginary region R1 (FIG. 5B, FIG. 6A, and FIG. 6B).

In this case, for example, the outer edge 41aa of the step portion 41 is not limited to be shaped so as to follow the side surfaces of the support substrate 3, and thus, the degree of freedom when designing the entire composite substrate 2 is large. As a result, for example, the orientation of the outer edge 41aa may be easily set to an effective orientation with respect to scattering and/or reflection of an acoustic wave.

The acoustic wave device 1 may further include the two reflectors 21 located on opposite sides of the excitation electrode 19 in the acoustic wave propagation direction (the D1 direction). Each of the reflectors 21 may include the plurality of strip electrodes 33 arranged in the D1 direction. In each of the reflectors 21, the number of the plurality of strip electrodes 33 may be 10 or smaller.

In this case, for example, spurious is reduced by the step portion 41 as described above, and thus, the probability of generation of large spurious is reduced even if the number of the strip electrodes 33 is set to 10 or smaller. By setting the number of the strip electrodes 33 to 10 or smaller, the acoustic wave device 1 may be easily reduced in size.

A distance d1 between a portion of the outer edge of the piezoelectric film 7 that is located in the imaginary region R1 and the excitation electrode 19 may be not more than ten times the pitch of the plurality of electrode fingers 27.

In this case, for example, spurious is reduced by the step portion 41 as described above, and thus, even if the distance d1 is shortened, the probability that large spurious will be generated due to the acoustic wave reflected at the outer edge of the piezoelectric film 7 (from another standpoint, the side surfaces of the piezoelectric film 7) is reduced. By shortening the distance d1, the acoustic wave device 1 may be easily reduced in size.

### EXAMPLE

For the acoustic wave device 1 according to the embodiment or the variations, specific parameter values were set, and the electrical characteristics of the acoustic wave device 1 were determined by a simulation calculation. Then, it was confirmed that various effects (the above-mentioned effects and effects not yet mentioned) were obtained by the step portion 41. Specific effects are as follows.

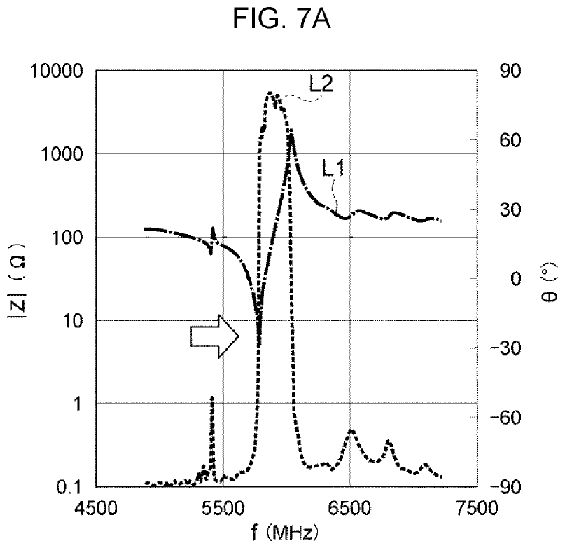

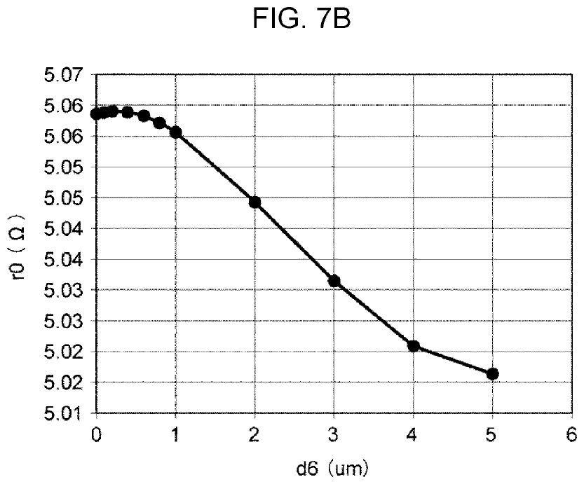

FIG. 7A is a graph illustrating characteristics relating to the impedance of the resonator 15 according to an example.

In FIG. 7A, the horizontal axis denotes frequency f (MHz). The vertical axis on the left-hand side denotes the absolute value of the impedance |Z|(Ω). The vertical axis on the right-hand side denotes the phase θ(°) of the impedance. The line L1 represents the value of |Z| of the resonator 15. The line L2 represents the value of θ of the resonator 15.

As is well known, the resonator 15 has a resonant frequency (about 5800 MHz in the example illustrated in FIG. 7A) at which the value of |Z| is a minimal value and an antiresonant frequency (about 6000 MHz in the example illustrated in FIG. 7A) at which the value of |Z| is a maximal value. The value of θ is large between the resonant frequency and the antiresonant frequency. In general, in the resonator 15 that is considered to have favorable characteristics, |Z| at the resonant frequency is small, and |Z| at the antiresonant frequency is large. In addition, the value of θ within the range between the resonant frequency and the antiresonant frequency is close to 90°, and the value of θ outside the above range is close to −90°.

FIG. 7B is a graph illustrating a resonant resistance r0 of the resonator 15.

In FIG. 7B, the horizontal axis denotes the length d6 (μm) of each of the treads 41a. The vertical axis denotes resonant resistance r0 (Ω). The resonant resistance r0 is the absolute value |Z| of the impedance at the resonant frequency. The line in FIG. 7B represents the value of r0 of the resonator 15.

Here, a composite substrate that is the same as, and/or similar to, each of those of the embodiment and the first variation (FIG. 4A) was assumed as the composite substrate 2. In other words, as in the embodiment, the outer edges 41aa of the treads 41a are perpendicular to the acoustic wave propagation direction (the D1 direction). The treads 41a have the same length d6. Each step of the step portion 41A includes two of the plurality of films (7 and 11) of the multilayer portion 4. In the resonator 15, the number of the plurality of electrode fingers 27 was set to 50. The number of the strip electrodes 33 in each of the reflectors 21 was set to 10. The pitch p was set to 1 μm.

In FIG. 7B, an aspect in which the length d6 is zero corresponds to an aspect in which the side surfaces of the composite substrate 2 do not include the step portion 41 (i.e., a comparative example). By providing the step portion 41 and by increasing the length d6, the resonant resistance r0 is reduced. In other words, the resonator 15 may have improved characteristics. In particular, when the length d6 is 1 (equivalent to 1 p) or more, the effect of reducing the resonant resistance r0 becomes notable. However, when the length d6 exceeds 4 (equivalent to 4p), the effect of reducing the resonant resistance r0 is somewhat reduced. When the length d6 is less than 0.5 p, the effect of reducing the resonant resistance r0 was not obtained. From the above, the length d6 may be set to 0.5 p or more or 1 p or more and may be 5 p or less or 4 p or less from the standpoint of the resonant resistance r0, and the above-mentioned lower limit and the above-mentioned upper limit may be suitably combined.

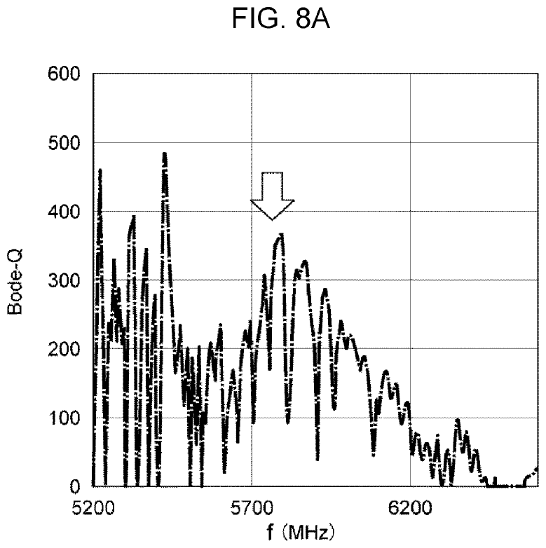

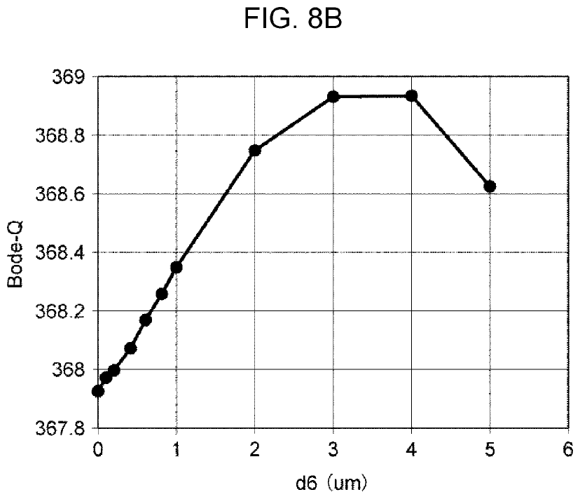

FIG. 8A is a graph illustrating a characteristic relating to the Bode-Q of the resonator 15 according to the example.

In FIG. 8A, the horizontal axis denotes frequency f (MHz). The vertical axis denotes Bode-Q (dimensionless quantity). The line in FIG. 8A represents the value of the Bode-Q of the resonator 15. Bode-Q is a Q value based on Bode's theory, and the larger the Bode-Q, the better the characteristics of the resonator 15. An arrow illustrated in FIG. 8A points the Bode-Q near a resonant frequency (about 5800 MHz in the case illustrated in FIG. 8A). The Bode-Q is large near the resonant frequency.

FIG. 8B is a graph illustrating values of the Bode-Q of the resonator 15 at a resonant frequency.

In FIG. 8B, the horizontal axis denotes the length d6 (μm) of each of the treads 41a. The vertical axis denotes Bode-Q (dimensionless quantity). The line in FIG. 8B represents values of the Bode-Q of the resonator 15. The conditions of the composite substrate 2 and the resonator 15 are the same as, and/or similar to, those in FIG. 7B.

In FIG. 8B, an aspect in which the length d6 is zero corresponds to an aspect in which the side surfaces of the composite substrate 2 do not include the step portion 41 (i.e., the comparative example). By providing the step portion 41 and by increasing the length d6, the Bode-Q becomes large. In other words, the characteristics of the resonator 15 are improved. More specifically, when the length d6 slightly exceeds 0 μm, the Bode-Q becomes large. However, when the length d6 exceeds 2 μm (equivalent to 2 p), a Bode-Q increasing effect is somewhat reduced, and when the length d6 reaches 4 μm (equivalent to 4 p), the Bode-Q increasing effect reaches its peak. Note that, although the effect reaches its peak, the Bode-Q increasing effect is obtained compared to the comparative example. From the above, the length d6 may be set to greater than 0 p and 5 p or less (or 4 p or less or 2 p or less) from the standpoint of the effect of Bode-Q.

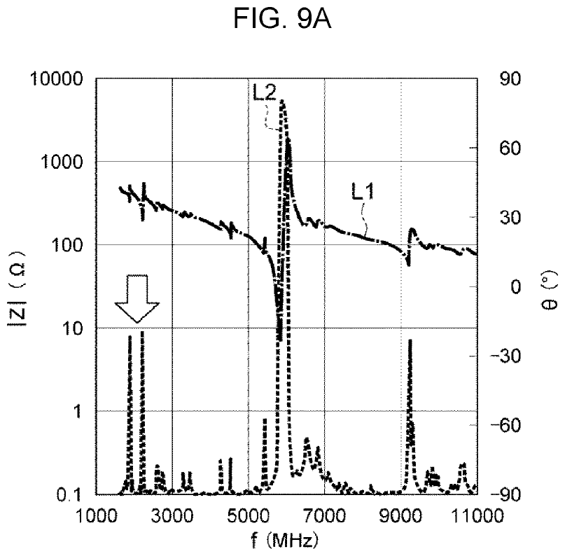

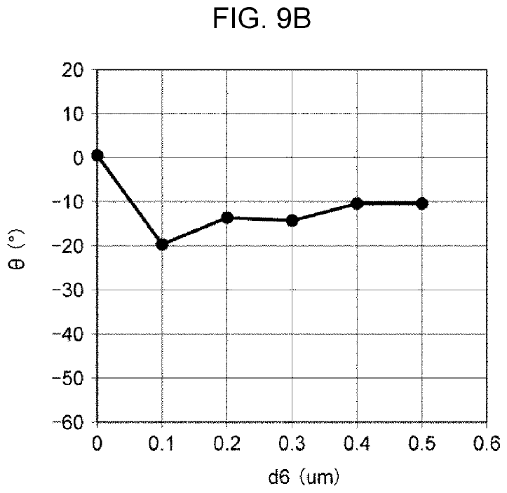

FIG. 9A is a graph illustrating characteristics relating to the impedance of the resonator 15 according to the example.

FIG. 9A illustrates the characteristics of the impedance of the resonator 15 within a frequency range wider than that illustrated in FIG. 7A. The horizontal axis and the vertical axis in FIG. 9A are the same as, and/or similar to, the horizontal axis and the vertical axis in FIG. 7A, except for a specific range of values on the horizontal axis. As indicated by an arrow in FIG. 9A, in the resonator 15, spurious may sometimes be generated at a frequency (e.g., about 2000 MHz in the case illustrated in FIG. 9A) relatively distant from the resonant frequency and the antiresonant frequency.

FIG. 9B is a graph illustrating the phase θ of the impedance in the spurious (about 2000 MHz) illustrated in FIG. 9A.

In FIG. 9B, the horizontal axis denotes the length d6 (μm) of each of the treads 41a. The vertical axis denotes the phase θ(°) of the impedance at the spurious (about 2000 MHz). The line in FIG. 9B represents the value of θ of the resonator 15.

Here, a composite substrate that is the same as, and/or similar to, that of the embodiment was assumed as the composite substrate 2. In other words, the outer edges 41aa of the treads 41a are perpendicular to the acoustic wave propagation direction (the D1 direction) as in the embodiment. The treads 41a have the same length d6. Each step of the step portion 41A includes one of the plurality of films (7 and 11) of the multilayer portion 4. In the resonator 15, the number of the plurality of electrode fingers 27 was set to 50. The number of the strip electrodes 33 in each of the reflectors 21 was set to 5. The pitch p was set to 1 μm.

In FIG. 9B, an aspect in which the length d6 is zero corresponds to an aspect in which the side surfaces of the composite substrate 2 do not include the step portion 41 (i.e., the comparative example). By providing the step portion 41, the spurious (specifically, θ) becomes small. More specifically, when the length d6 slightly exceeds 0 μm, the spurious is reduced. However, when the length d6 exceeds 0.1 μm (equivalent to 0.1 p), a spurious reduction effect becomes roughly constant (slightly decreases). From the above, the length d6 may suitably be set within a range exceeding 0 p from the standpoint of the spurious reduction effect.

(Branching Filter)

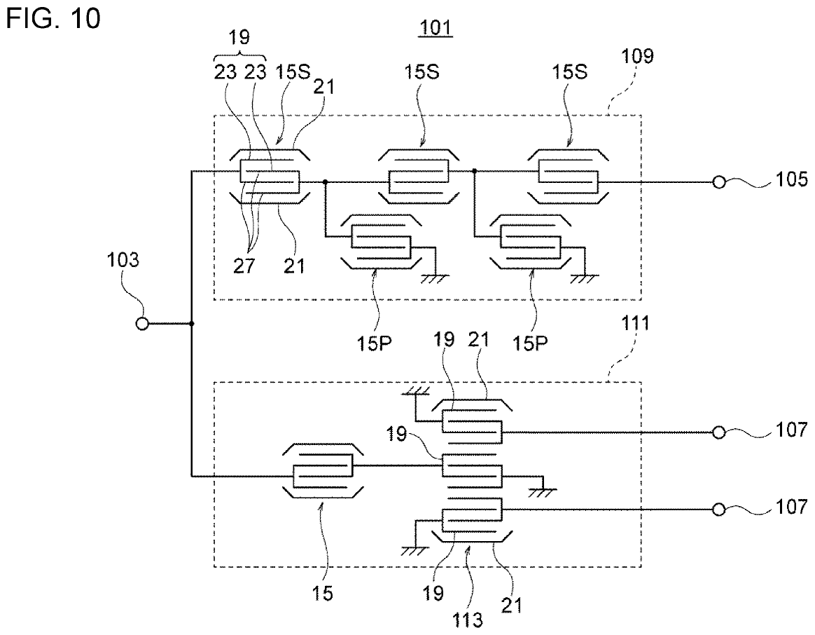

FIG. 10 is a circuit diagram schematically illustrating, as an example of how to use the acoustic wave device 1, a configuration of a branching filter 101. As understood from the reference signs illustrated on the upper left side in FIG. 10, the comb-shaped electrodes 23 are each schematically illustrated in the shape of a two-prong fork, and the reflectors 21 are each represented by a single line whose opposite ends are bent in FIG. 10.

More specifically, the branching filter 101 illustrated in FIG. 10 is configured as a duplexer. The branching filter 101 includes, for example, a transmission filter 109 that filters a transmission signal from a transmission terminal 105 and then outputs the transmission signal to an antenna terminal 103 and a reception filter 111 that filters a reception signal from the antenna terminal 103 and then outputs the reception signal to a pair of reception terminals 107.

The transmission filter 109 is formed of, for example, a ladder filter that includes a plurality of resonators 15 (15S and 15P) connected in a ladder configuration. In other words, the transmission filter 109 includes a plurality of serial resonators 15S (or a single serial resonator 15S) connected in series to one another between the transmission terminal 105 and the antenna terminal 103 and a plurality of parallel resonators 15P (or a single parallel resonator 15P) (a parallel arm) connecting the serial line (a serial arm) and a reference potential portion (with no reference sign).

The reception filter 111 includes, for example, the resonator 15 and a multi-mode filter (including a double-mode filter) 113. The multi-mode filter 113 includes a plurality of (three in the case illustrated in FIG. 10) excitation electrodes 19 that are arranged in the acoustic wave propagation direction and a pair of reflectors 21 that are arranged such that one of them is located on one side of the plurality of excitation electrodes 19 and the other is located on the other side of the plurality of excitation electrodes 19.

Like the above-described resonator 15, the plurality of resonator 15 (15S, 15P, and the resonator 15 of the reception filter 111) and the multi-mode filter 113 in the above-described configuration are formed by providing the conductor layer 9 onto the upper surface of the composite substrate 2. In other words, at least a portion of the branching filter 101 is formed of the acoustic wave device 1 that has been described above. The antenna terminal 103, the transmission terminal 105, the reception terminals 107, and the reference potential portion each correspond to, for example, the terminal 17A or 17B schematically illustrated in FIG. 1 and may each be formed of the conductor layer 9.

The plurality of excitation electrodes 19 (and the reflectors 21) of the branching filter 101 may be provided on a single composite substrate 2 or may be provided on two or more composite substrates 2 in a distributed manner. For example, the plurality of resonators 15 included in the transmission filter 109 may be provided on, for example, the same composite substrate 2. Similarly, the resonator 15 and the multi-mode filter 113 included in the reception filter 111 may be provided on, for example, the same composite substrate 2. The transmission filter 109 and the reception filter 111 may be provided on, for example, the same composite substrate 2 or may be provided on different composite substrates 2. Alternatively, for example, the plurality of serial resonators 15S may be provided on the same composite substrate 2, and the plurality of parallel resonators 15P may be provided the same composite substrate 2, which is different from the composite substrate 2 on which the plurality of serial resonators 15S may be provided.

From another standpoint, the acoustic wave device 1 including the single composite substrate 2 may form the entire branching filter 101 or may form only a portion of the branching filter 101. The acoustic wave device 1 may form the entire filter (e.g., the transmission filter 109 or the reception filter 111) or may form only a portion of the filter. As illustrated in the schematic diagram in FIG. 1, the acoustic wave device 1 may simply form the resonator 15.

Note that, as understood from the above description, the acoustic wave device 1 does not necessarily include a one-port-type acoustic wave resonator (the resonator 15). For example, the acoustic wave device 1 does not necessarily include the resonator 15 and may include the multi-mode filter 113. The configuration of the duplexer illustrated in FIG. 10 is merely an example. For example, the reception filter 111 may be formed of a ladder filter like the transmission filter 109. Conversely, the transmission filter 109 may include the multi-mode filter 113.

(Communication Device)

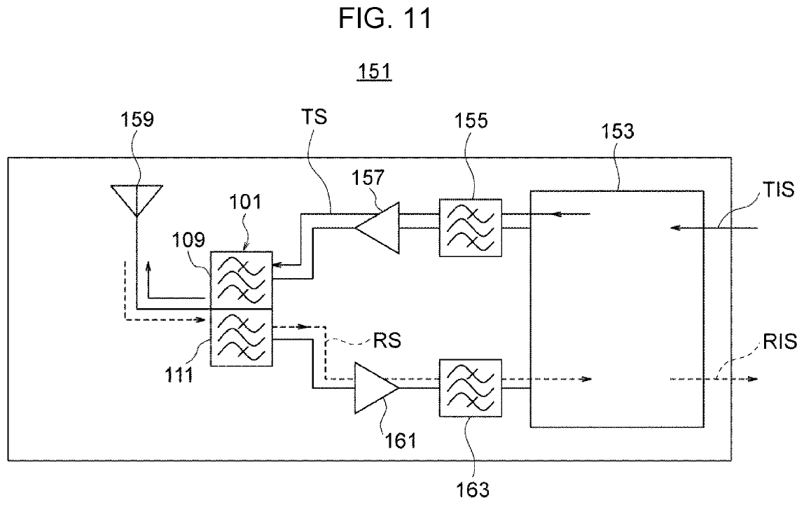

FIG. 11 is a block diagram illustrating, as an example of how to use the acoustic wave device 1 (from another standpoint, the branching filter 101), a principal portion of a communication device 151. The communication device 151 performs wireless communication using radio waves and includes, for example, the above-described branching filter 101.

In the communication device 151, a transmission information signal TIS including information to be transmitted is modulated by a radio frequency integrated circuit (RF-IC) 153, and the frequency of the transmission information signal TIS is increased by the RF-IC 153 (converted into a high-frequency signal having a carrier frequency) such that the transmission information signal TIS becomes a transmission signal TS. A bandpass filter 155 removes an unnecessary component outside a transmission passband from the transmission signal TS, and the transmission signal TS is amplified by an amplifier 157. Then, the transmission signal TS is input to the branching filter 101 (the transmission terminal 105). Subsequently, the branching filter 101 (the transmission filter 109) removes an unnecessary component outside the transmission passband from the transmission signal TS input thereto, and after the removal, the transmission signal TS is output from the antenna terminal 103 to an antenna 159. The antenna 159 converts an electrical signal (the transmission signal TS) input thereto into a radio signal (radio waves) and transmits the radio signal.

In the communication device 151, the radio signal (radio waves) received by the antenna 159 is converted into an electrical signal (a reception signal RS) by the antenna 159 and input to the branching filter 101 (the antenna terminal 103). The branching filter 101 (the reception filter 111) removes an unnecessary component outside a reception passband from the reception signal RS input thereto and then outputs the reception signal RS from the reception terminals 107 to an amplifier 161. The output reception signal RS is amplified by the amplifier 161, and an unnecessary component outside the reception passband is removed from the reception signal RS by a band-pass filter 163. Then, the frequency of the reception signal RS is increased by the RF-IC 153, and the reception signal RS is demodulated by the RF-IC 153 such that the reception signal RS becomes a reception information signal RIS.

Note that the transmission information signal TIS and the reception information signal RIS may each be a low-frequency signal (a baseband signal) containing appropriate information and are each, for example, an analog voice signal or a digitized signal. the passband of the radio signal may be suitably set and may be a relatively high frequency passband (e.g., 5 GHz or higher). The modulation method may be phase modulation, amplitude modulation, frequency modulation, or a combination of two or more of these. Although a direct conversion system is illustrated in FIG. 11 as an example of a circuit system, the circuit system may be an appropriate system other than the direct conversion system and may be, for example, a double superheterodyne system. FIG. 11 schematically illustrates only the principal portion, and a low-pass filter, an isolator, or the like may be added at a suitable position, or the position of the amplifier or the like may be changed.

The technology according to the present disclosure is not limited to the above-described embodiment and the above-described variations and may be implemented in various aspects.

An acoustic wave that is intended to be used is not limited to a slab-mode acoustic wave and may be a general SAW, a boundary acoustic wave (which is a type of SAW in a broad sense), or a BAW. For example, as in the embodiment, these acoustic waves may be excited by an excitation electrode formed of an IDT electrode including a pair of comb-shaped electrodes.

The excitation electrode is not limited to an IDT electrode. For example, the acoustic wave device may be a solid mounted resonator (SMR)-type BAW resonator including two excitation electrodes that are arranged so as to face each other in a thickness direction thereof with a piezoelectric film interposed therebetween. In other words, the acoustic wave device may include an excitation electrode located on the upper surface of the piezoelectric film and an excitation electrode located on the lower surface of the piezoelectric film. In this case, each of the excitation electrodes may have a flat plate-like shape.

In the embodiment, each step of the step portion has a minimum height, and the height is set to be equal to the thickness of one of the films included in the multilayer portion. However, by forming a step on the side surfaces of one of the films, the height of each step may be less than the thickness of the one film.

### REFERENCE SIGNS

1 acoustic wave device
2 composite substrate
3 support substrate
5 multilayer film
7 piezoelectric film
11 (11A, 11B) acoustic film
19 excitation electrode
41 step portion

1. An acoustic wave device comprising:
a composite substrate; and
an excitation electrode located on an upper surface of the composite substrate,
wherein the composite substrate includes
a support substrate,
a multilayer film including a plurality of acoustic films stacked on an upper surface of the support substrate, adjacent ones of the acoustic films in a direction in which the acoustic films are stacked being made of different materials, and
a piezoelectric film overlapping the upper surface of the multilayer film,
wherein the excitation electrode is located on an upper surface of the piezoelectric film, and
wherein a side surface of the composite substrate includes a step portion having a step-like shape with two or more steps ascending from the support substrate side to the piezoelectric film side in a direction from an outside to an inside with respect to the side surface.

2. The acoustic wave device according to claim 1,
wherein the step portion includes a tread made of an upper surface of at least one of the acoustic films located below the acoustic film that is an uppermost layer in the multilayer film.

3. The acoustic wave device according to claim 1,
wherein the step portion includes the upper surface of the piezoelectric film as an upper most tread, and at least two steps including an uppermost step are each made of one or two films selected from a group consisting of the plurality of acoustic films and the piezoelectric film.

4. The acoustic wave device according to claim 3,
wherein the step portion extends from the upper surface of the support substrate to the upper surface of the piezoelectric film, and each step of the step portion is made of one or two films selected from the group consisting of the plurality of acoustic films and the piezoelectric film.

5. The acoustic wave device according to claim 1,
wherein at least two steps of the step portion that are continuous with each other are each made of only one film selected from the group consisting of the plurality of acoustic films and the piezoelectric film.

6. The acoustic wave device according to claim 1,
wherein the excitation electrode includes a plurality of electrode fingers arranged in a direction in which an acoustic wave propagates when the piezoelectric film is viewed in plan view, and
wherein, when the piezoelectric film is viewed in plan view, the step portion is located in an imaginary region that is formed by extending, along the propagation direction, a region in which the plurality of electrode fingers is arranged to an area outside of the composite substrate.

7. The acoustic wave device according to claim 6,
wherein, when the piezoelectric film is viewed in plan view, at least one of the steps of the step portion includes a portion that is located in the imaginary region and in which a descending-side edge of the tread is inclined with respect to a direction perpendicular to the propagation direction.

8. The acoustic wave device according to claim 7,
wherein, when the piezoelectric film is viewed in plan view, at least one of the steps of the step portion includes a portion that is located in the imaginary region and in which the descending-side edge of the tread extends while being repeatedly bent to opposite sides.

9. The acoustic wave device according to claim 6,
wherein at least one of the steps of the step portion includes the tread made of the upper surface of one of the plurality of acoustic films, and when the piezoelectric film is viewed in plan view, the at least one step includes a portion that is located in the imaginary region and in which a length of the tread in a direction parallel to the propagation direction varies depending on a position in the direction perpendicular to the propagation direction.

10. The acoustic wave device according to claim 6,
wherein at least two steps of the step portion each include the tread made of the upper surface of one of the plurality of acoustic films, and in the imaginary region, the treads have different lengths in the propagation direction.

11. The acoustic wave device according to claim 6,
wherein, when the piezoelectric film is viewed in plan view, at least one of the steps of the step portion includes a portion that is located in the imaginary region and in which the descending-side edge of the tread is inclined with respect to a portion of a side surface of the support substrate, the portion of the side surface being located in the imaginary region.

12. The acoustic wave device according to claim 6, further comprising:
two reflectors arranged on opposite sides of the excitation electrode in the propagation direction,
wherein each of the reflectors includes a plurality of strip electrodes arranged in the propagation direction, and
wherein the strip electrodes included in each of the reflectors include not more than 10 strip electrodes.

13. The acoustic wave device according to claim 6,
wherein a distance between a portion of an outer edge of the piezoelectric film, the portion being located in the imaginary region, and the excitation electrode is not more than ten times a pitch of the plurality of electrode fingers.

14. A communication device comprising:
the acoustic wave device according to claim 1;
an antenna connected to the acoustic wave device; and
an integrated circuit element connected to the acoustic wave device.
